(19) United States
(12) Patent Application Publication
(10) Pub. No.: US 2026/0107732 A1
(43) Pub. Date: Apr. 16, 2026

(54) SUBSTRATE PROCESSING METHOD AND SUBSTRATE PROCESSING APPARATUS

(71) Applicant: Tokyo Electron Limited, Tokyo (JP)

(72) Inventor: Yukinobu MIYAMOTO, Koshi City (JP)

(21) Appl. No.: 19/358,506

(22) Filed: Oct. 15, 2025

(30) Foreign Application Priority Data
Oct. 15, 2024 (JP) 2024-179702

(51) Int. Cl. H01L 21/67; G03F 1/42; G03F 7/00; H01L 21/66

(52) U.S. Cl. CPC H10P 72/0616; G03F 7/70066; G03F 7/70366; G03F 7/705; G03F 7/70508; G03F 7/70525; G03F 7/70725; G03F 7/70775; G03F 7/70783; G03F 7/7085; H10P 72/0606; H10P 74/203; G03F 1/42

(57) ABSTRACT

A substrate processing method includes: generating edge information indicating a relationship between a circumferential position around a center of a substrate and an outer edge position of a first film in a radial direction of the substrate based on an image obtained by capturing a peripheral edge region on a front surface of the substrate; setting an exposure map indicating a relationship between the circumferential position and a set value of an exposure width in the radial direction based on the edge information; forming a second film on at least the peripheral edge region of the front surface; obtaining warpage information of the substrate after the second film is formed; setting a relationship between the circumferential position and exposure position information of the substrate in the exposure map based on the warpage information; and exposing the second film in the peripheral edge region in accordance with the exposure map.

### CROSS-REFERENCE TO RELATED APPLICATION

This application is based upon and claims the benefit of priority from Japanese Patent Application No. 2024-179702, filed on Oct. 15, 2024, the entire contents of which are incorporated herein by reference.

### TECHNICAL FIELD

The present disclosure relates to a substrate processing method and a substrate processing apparatus.

### BACKGROUND

Patent Document 1 discloses a substrate processing apparatus. This substrate processing apparatus obtains an amount of warpage of a substrate having a film formed thereon from a captured image, and controls a peripheral edge exposure width based on the amount of warpage.

### PRIOR ART DOCUMENT

### Patent Document

Patent Document 1: Japanese Laid-Open Patent Publication No. 2017-150849

### SUMMARY

According to one embodiment of the present disclosure, a substrate processing method includes: generating edge information indicating a relationship between a circumferential position around a center of a substrate and an outer edge position of a first film in a radial direction of the substrate based on an image obtained by capturing a peripheral edge region on a front surface of the substrate having the first film formed on the front surface; setting an exposure map indicating a relationship between the circumferential position and a set value of an exposure width in the radial direction based on the edge information; forming a second film on at least the peripheral edge region of the front surface after the image is obtained; obtaining warpage information of the substrate after the second film is formed; setting a relationship between the circumferential position and exposure position information of the substrate in the exposure map based on the warpage information; and performing an exposure on the second film in the peripheral edge region in accordance with the exposure map.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing an example of a wafer processing system.

FIG. 2 is a front view schematically showing the example of the wafer processing system.

FIG. 3 is a schematic view showing an example of a liquid processing apparatus.

FIG. 4 is a plan view schematically showing an example of an inspection apparatus.

FIG. 5 is a front view schematically showing the example of the inspection apparatus.

FIG. 6A is a schematic view showing an example of a periphery exposure apparatus, and

FIG. 6B is a side view schematically showing an example of a mask member.

FIG. 7 is a block diagram showing an example of a functional configuration of a control device.

FIG. 8 is a block diagram showing an example of a hardware configuration of the control device.

FIG. 9 is a flowchart showing an example of a substrate processing method.

FIGS. 10A to 10F are schematic diagrams illustrating the substrate processing method.

FIG. 11A is a diagram showing an example of a peripheral edge image and FIG. 11B is a graph showing an example of edge information.

FIG. 12A is a graph visually indicating an example of an exposure map and FIG. 12B is a diagram schematically showing an example of a state of a film after exposure and development.

FIG. 13 is a graph showing an example of a relationship between edge information and an exposure map.

FIG. 14A is a graph showing an example of measurement results of an exposure width after exposure and FIG. 14B is a graph showing an example of difference information obtained in an inspection process.

FIGS. 15A to 15F are schematic diagrams illustrating each operation of the substrate processing method.

FIGS. 16A to 16D are schematic diagrams illustrating each operation of the substrate processing method.

FIG. 17A is a schematic diagram illustrating an effect of warpage and FIG. 17B is a schematic diagram showing an example of a periphery exposure apparatus.

FIG. 18 is a schematic diagram showing another example of the periphery exposure apparatus.

FIG. 19 is a schematic diagram showing another example of the periphery exposure apparatus.

FIG. 20 is a flowchart showing an example of the substrate processing method.

FIG. 21A is a graph showing an example of measurement results of edge information, FIG. 21B is a graph showing an example of measurement results at a Z-direction position of a substrate peripheral edge portion, and FIG. 21C is a graph showing an example of a correlation formula that indicates a position of a rotary holder from the measurement results at the Z-direction position of the substrate peripheral edge portion.

FIG. 22 is a graph showing an example of a relationship between an exposure map and an exposure width.

### DETAILED DESCRIPTION

An embodiment will be described below with reference to the drawings. In the descriptions, the same elements or elements having the same functions are designated by like reference numerals, and redundant descriptions thereof will be omitted. Some of the drawings show a Cartesian coordinate system defined by an X-axis, a Y-axis, and a Z-axis. In the following embodiment, the X-axis and the Y-axis correspond to a horizontal direction, and the Z-axis corresponds to an up-down direction. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Wafer Processing System>

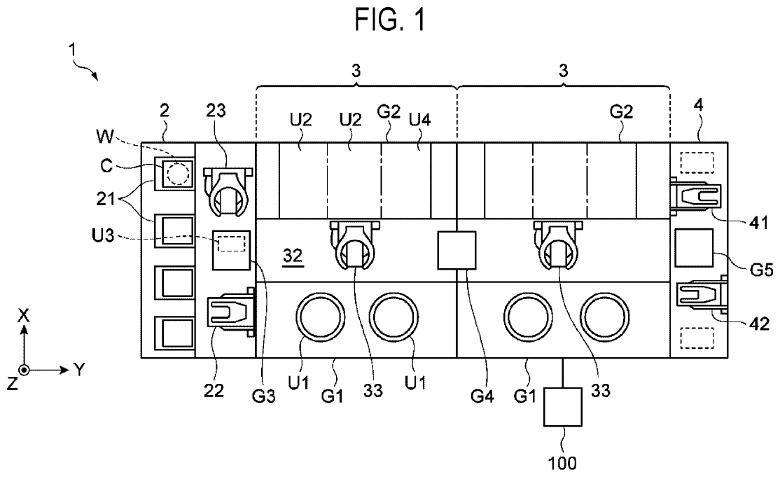

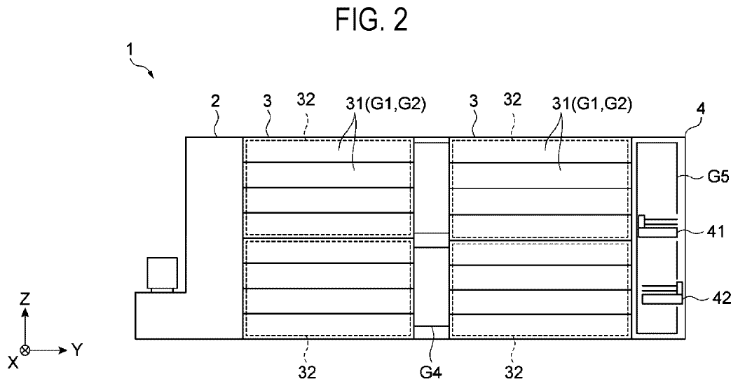

First, a configuration of a wafer processing system according to this embodiment will be described. FIGS. 1 and 2 are a plan view and a front view schematically showing an overall configuration of a wafer processing system 1, respectively. In this embodiment, the wafer processing system 1 (substrate processing apparatus) will be described as an example of a photolithography processing system that performs a resist film formation process and a development process on wafers W (substrates).

As shown in FIG. 1, the wafer processing system 1 includes a cassette station 2 into and from which a cassette C accommodating the plurality of wafers W is loaded and unloaded, and a processing station 3 equipped with a plurality of various processing apparatuses that perform predetermined processing on the wafers W. The wafer processing system 1 is constituted by integrally connecting the cassette station 2, the processing station 3, and an interface station 4 that delivers the wafers W to and from an exposure apparatus (not shown) adjacent to the interface station 4 on an opposite side of the processing station 3. As shown in FIG. 1, two processing stations 3 are installed between the cassette station 2 and the interface station 4, but one, or three or more processing stations may be installed.

The cassette station 2 is provided with a plurality of cassette stages 21, a wafer transfer device 22, and a wafer transfer device 23. In the cassette station 2, the wafer transfer device 22 or the wafer transfer device 23 transfers the wafers W between the cassette C placed on the cassette stage 21 and the processing station 3. To this end, each of the wafer transfer device 22 and the wafer transfer device 23 includes drive mechanisms corresponding to the X-axis direction, the Y-axis direction, the up-down direction, and a direction around the vertical axis (0 direction) as needed, and may also include drive mechanisms corresponding to all directions. At least one of the wafer transfer device 22 or the wafer transfer device 23 is capable of delivering the wafers W to and from the cassette C, and also capable of delivering the wafers W to and from the processing station 3. An operation of delivering the wafers W to and from the processing station 3 refers to, for example, delivering the wafers W to and from a third block G3 that includes a delivery device accessible by a wafer transfer device 33 in the processing station 3 (to be described later). The third block G3 may include a plurality of delivery devices (not shown) arranged along the up-down direction.

An inspection apparatus U3 that inspects the wafers W may be arranged at a position accessible by either the wafer transfer device 22 or the wafer transfer device 23. The inspection apparatus U3 may be arranged in the cassette station 2 (for example, the third block G3). Instead of or in addition to the cassette station 2, the inspection apparatus U3 may be arranged in the processing station 3 or in the interface station 4.

The processing station 3 includes a plurality of blocks, such as a first block G1, a second block G2, and a fourth block G4. As shown in FIG. 2, a plurality of floors 31 each including the first block G1 and the second block G2 are stacked one above another in the up-down direction. For example, the first block G1 is provided on a front side of the processing station 3 (on a negative X-direction side in FIG. 1), and the second block G2 is provided on a rear side of the processing station 3 (on a positive X-direction side in FIG. 1). The fourth block G4 is provided at a connection portion between the processing station 3 located on the side of the cassette station 2 (the negative Y-direction side in FIG. 1) and the processing station 3 located on the side of the interface station 4 (the positive Y-direction side in FIG. 1). The fourth block G4 may include a plurality of delivery devices arranged in the up-down direction. The aforementioned third block G3 may also be provided inside the processing station 3.

A plurality of film processing apparatuses U1 are arranged in the first block G1. The film processing apparatuses U1 are, for example, patterning film forming apparatuses and developing apparatuses. The patterning film forming apparatuses may include, for example, a resist film forming apparatus and an anti-reflection film forming apparatus. At least some of the plurality of film processing apparatuses U1 may be apparatuses that perform film processing using a processing liquid. The film processing includes forming a film and performing a developing process.

In the first block G1, for example, the plurality of film processing apparatuses U1 are arranged in the horizontal direction. The number, arrangement, and type of the film processing apparatuses U1 may be selected arbitrarily.

In the patterning film forming apparatus and the developing apparatus, for example, a predetermined processing liquid or a predetermined gas is supplied onto the wafer W. In this manner, the patterning film forming apparatus forms a resist film used as a mask when forming a pattern of an underlying film, or forms an anti-reflection film for efficiently performing a light irradiation process, such as an exposure process. On the other hand, in the developing apparatus, a portion of the exposed resist film is removed to form an uneven shape that serves as the mask.

For example, in the second block G2, heat treatment apparatuses U2 for performing heat treatments such as heating and cooling of the wafer W are provided in the up-down direction and the horizontal direction. Further, in the second block G2, hydrophobization processing apparatuses (not shown) for performing a hydrophobization process to improve adhesion of the resist liquid to the wafer W, and periphery exposure apparatuses U4 for exposing a peripheral portion of the wafer W are arranged in the up-down direction (in the Z direction in FIG. 2) and the horizontal direction. The number and arrangement of these heat treatment apparatuses, hydrophobization processing apparatuses, and periphery exposure apparatuses U4 may be selected arbitrarily. The periphery exposure apparatus U4 may be located in the interface station 4 instead of or in addition to the processing station 3 (for example, the second block G2). Both the inspection apparatus U3 and the periphery exposure apparatus U4 may be located in the processing station 3 or in the interface station 4.

As shown in FIG. 1, a wafer transfer region area 32 is formed in a region sandwiched between the first block G1 and the second block G2 in a plan view. For example, a wafer transfer device 33 is arranged in the wafer transfer region 32.

The wafer transfer device 33 includes a transfer arm that is movable in, for example, the Y-axis direction, the front-rear direction, the θ direction, and the up-down direction. The wafer transfer device 33 moves inside the wafer transfer region 32 and may transfer the wafer W to predetermined apparatuses in the first block G1, the second block G2, the third block G3, and the fourth block G4 positioned therearound. When a plurality of processing stations 3 is provided as shown in FIG. 1, the wafer transfer device 33 provided in the processing station 3 located on the interface station 4 side may transfer the wafer W to predetermined apparatuses in the first block G1, the second block G2, and the fourth block G4, as well as the fifth block G5 described below.

A plurality of wafer transfer devices 33 are arranged, for example, one above another. One wafer transfer device 33 may transfer the wafer W to predetermined apparatuses located at heights of the upper floors 31 among the plurality of floors 31 stacked one above another. Another wafer transfer device 33 may transfer the wafer W to predetermined apparatuses located at heights of the floors 31 below the upper floors 31. A plurality of wafer transfer regions 32 (see regions arranged one above another in FIG. 2) are provided to enable such transfer of the wafer W. The number of wafer transfer devices 33 and the number of floors 31 corresponding to one wafer transfer device 33 may be selected arbitrarily by, for example, providing the wafer transfer device 33 for each floor 31.

Further, the wafer transfer region 32, the first block G1, or the second block G2 may also include a shuttle transfer device (not shown). The shuttle transfer device linearly transfers the wafer W between a space adjacent to one side of the processing station 3 and another space adjacent to the opposite side thereof.

The interface station 4 is provided with a fifth block G5 including a plurality of delivery devices, a wafer transfer device 41, and a wafer transfer device 42. The interface station 4 uses the wafer transfer device 41 or the wafer transfer device 42 to transfer the wafer W between the fifth block G5 where the wafer W is delivered by the wafer transfer device 33, and the exposure apparatus. To this end, each of the wafer transfer device 41 and the wafer transfer device 42 includes drive mechanisms corresponding to the X-axis direction, the Y-axis direction, the up/down direction, and the direction around the vertical axis (θ direction) as needed, and may also include drive mechanisms corresponding to all directions. At least one of the wafer transfer device 41 or the wafer transfer device 42 may support the wafer W and may transfer the wafer W between the delivery device in the fifth block G5 and the exposure apparatus.

A cleaning apparatus that cleans the surface of the wafer W and the aforementioned periphery exposure apparatus U4 may be provided inside the interface station 4 at positions accessible by either the wafer transfer device 41 or the wafer transfer device 42. In one example, the cleaning apparatus and the periphery exposure apparatus U4 may be provided at locations indicated by dashed squares in the interface station 4 in FIG. 1.

The wafer processing system 1 described above is provided with a control device 100. The control device 100 is, for example, a computer, and includes a program storage (not shown). The program storage stores a program for controlling the processing of wafers W in the wafer processing system 1. The program storage also stores a program for controlling operations of the drive systems of the various processing apparatuses and transfer devices described above to implement the wafer processing in the wafer processing system 1. The program may be recorded in a non-transitory computer-readable storage medium H and installed in the control device 100 from the storage medium H.

### <Operation of Wafer Processing System>

The wafer processing system 1 is configured as described above. Next, an example of the wafer processing performed by the above-described wafer processing system 1 will be described.

First, the cassette C accommodating the plurality of wafers W is loaded into the cassette station 2 of the wafer processing system 1 and placed on the cassette stage 21. Next, the wafers W in the cassette C are sequentially taken out by the wafer transfer device 22 or the wafer transfer device 23 and transferred to the delivery device in the third block G3.

The wafer W transferred to the delivery device in the third block G3 is supported by the wafer transfer device 33 and transferred to the hydrophobization processing apparatus provided in the second block G2, where the hydrophobization processing is performed. The wafer W is then transferred by the wafer transfer device 33 to the resist film forming apparatus where a resist film is formed on the wafer W, and then transferred to the heat treatment apparatus where a pre-bake treatment is performed. Thereafter, the wafer W is transferred to the delivery device in the fifth block G5. In the case in which the plurality of processing stations 3 is provided as shown in FIGS. 1 and 2, the wafer W is temporarily placed in the delivery device in the fourth block G4 before being transferred to the delivery device in the fifth block G5, and is then transferred to and from the plurality of wafer transfer devices 33. The wafer W is also transferred by the wafer transfer device 33 to the periphery exposure apparatus U4 where the exposure processing is performed on the peripheral edge region of the wafer W.

The wafer W transferred to the delivery device in the fifth block G5 is transferred by the wafer transfer device 41 and the wafer transfer device 42 to the exposure apparatus connected to the interface station 4 where the wafer W is exposed in a predetermined pattern. The wafer W may be cleaned in the cleaning apparatus before the exposure processing.

The exposed wafer W is transferred to the delivery device in the fifth block G5 by the wafer transfer device 41 and the wafer transfer device 42. Thereafter, the wafer W is transferred to the heat treatment apparatus by the wafer transfer device 33 and subjected to a post-exposure baking.

The wafer W that has been subjected to the post-exposure baking is transferred by the wafer transfer device 33 to the developing apparatus where the wafer W is developed. After the development is completed, the wafer W is transferred by the wafer transfer device 33 to the heat treatment apparatus U2 and is subjected to a post-baking.

Thereafter, the wafer W is transferred by the wafer transfer device 33 to the delivery device in the third block G3, and transferred by the wafer transfer device 22 or the wafer transfer device 23 in the cassette station 2 to the cassette C on a predetermined cassette stage 21. In this way, a series of photolithography operations is completed. The resist film may be formed on at least the peripheral edge region of the wafer W before or after exposure in the exposure apparatus. The resist film may be exposed in the periphery exposure apparatus U4, and then developed in the developing apparatus.

### <Liquid Processing Apparatus>

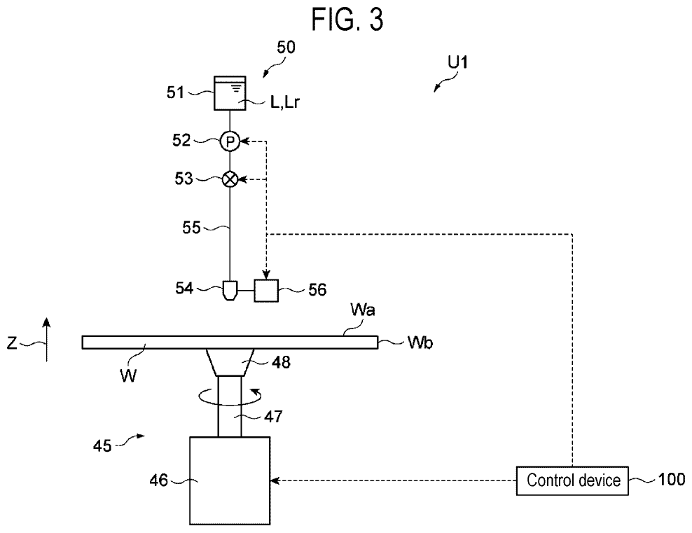

Next, referring to FIG. 3, a liquid processing apparatus that forms a film using a processing liquid will be described as an example of a film processing apparatus U1. In the present disclosure, a film of processing liquid formed by applying the processing liquid and a film formed by heat-treating the film of processing liquid are collectively referred to as a “film.” The film processing apparatus U1 includes, for example, a rotary holder 45 and a liquid supply 50.

The rotary holder 45 includes a rotary drive 46, a shaft 47, and a holder 48. The rotary drive 46 is operated based on an operation signal from the control device 100 to rotate the shaft 47. The rotary drive 46 includes a power source such as an electric motor. The holder 48 is provided at a tip of the shaft 47. The wafer W may be placed on the holder 48. The holder 48 is configured to hold the wafer W approximately horizontally, for example, by suction or the like. That is, the holder 48 rotates the wafer W around a central axis (rotation axis) perpendicular to a front surface Wa of the wafer W while the wafer W is positioned approximately horizontally.

The liquid supply 50 is configured to supply a processing liquid L to the front surface Wa of the wafer W. The processing liquid L is, for example, a resist liquid (hereinafter, referred to as a “processing liquid Lr”) for forming a resist film. The resist material contained in the processing liquid Lr may be a positive resist material or a negative resist material. The positive resist material is a resist material that dissolves in an exposed region and remains in an unexposed region. The negative resist material is a resist material that dissolves in an unexposed region and remains in an exposed region. The following description will be given using an example in which the processing liquid L is the processing liquid Lr and the resist material contained in the processing liquid Lr is the negative resist material.

The liquid supply 50 includes a liquid source 51, a pump 52, a valve 53, a nozzle 54, a pipe 55, and a drive mechanism 56. The liquid source 51 functions as a source of the processing liquid Lr. The pump 52 is operated based on an operation signal from the control device 100 to suction the processing liquid Lr from the liquid source 51 and send the same to the nozzle 54 via the pipe 55 and the valve 53.

The nozzle 54 is arranged above the wafer W so that a discharge port of the nozzle 54 faces the front surface Wa of the wafer W. The nozzle 54 is configured to discharge the processing liquid Lr sent by the pump 52 onto the front surface Wa of the wafer W. The pipe 55 connects the liquid source 51, the pump 52, the valve 53, and the nozzle 54 sequentially from the upstream side. The drive mechanism 56 is operated based on an operation signal from the control device 100, and is configured to move the nozzle 54 in the horizontal direction and the up-down direction.

In the film processing apparatus U1, the wafer W on which the film of the processing liquid Lr has been formed is transferred to one of the heat treatment apparatuses U2, which performs the heat treatment on the wafer W. This forms the resist film on the front surface Wa of the wafer W. As described above, the film processing apparatus U1 and the heat treatment apparatus U2 may constitute a film former that forms the resist film, which is a type of film.

### <Inspection Apparatus>

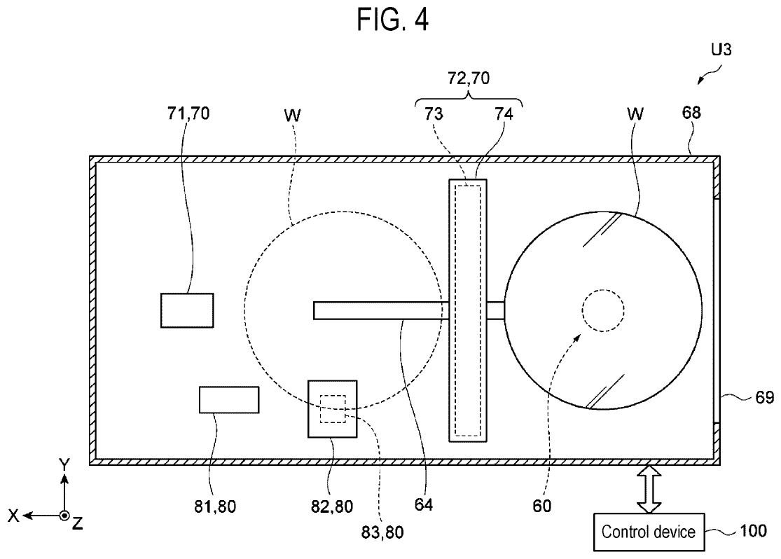

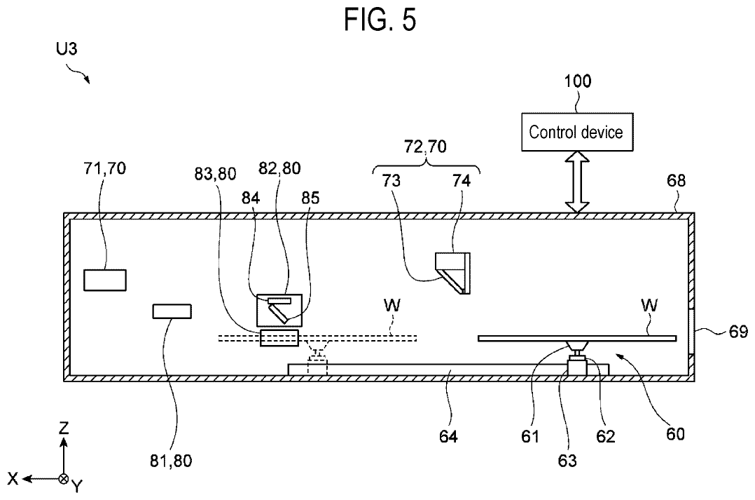

Next, an example of the inspection apparatus U3 will be described with reference to FIGS. 4 and 5. The inspection apparatus U3 (inspector) is an apparatus that generates one or more types of image information for inspecting a state of the wafer W. The inspection apparatus U3 includes, for example, a housing 68, a rotary holding unit 60, a surface capturing unit 70, and a peripheral edge capturing unit 80. The rotary holding unit 60, the surface capturing unit 70, and the peripheral edge capturing unit 80 are arranged inside the housing 68. One sidewall of the housing 68 is formed with a loading/unloading port 69 for loading the wafer W into the housing 68 and for unloading the wafer W from the housing 68.

The rotary holding unit 60 is a unit that holds and rotates the wafer W and moves the wafer W inside the housing 68. The rotary holding unit 60 includes a holding table 61, drive mechanisms 62 and 63, and a guide rail 64. The holding table 61 is, for example, a suction chuck that holds the wafer W substantially horizontally by suction or the like.

The drive mechanism 62 includes a power source such as an electric motor and rotationally drive the holding table 61. That is, the drive mechanism 62 rotates the wafer W held on the holding table 61. The wafer W may be placed on the holding table 61 so that the central axis of rotation by the drive mechanism 62 substantially coincides with the center of the wafer W. The drive mechanism 62 may include an encoder for detecting a rotation position (rotation angle) of the holding table 61 about the central axis. In this case, capturing positions of the wafer W by the surface capturing unit 70 and the peripheral edge capturing unit 80 may be associated with the rotation positions of the wafer W. When the wafer W includes an index portion (for example, a notch) indicating a reference position in the circumferential direction, the posture of the wafer W may be specified based on the index portion determined by the surface capturing unit 70 and the peripheral edge capturing unit 80, and the rotation position detected by the encoder.

The drive mechanism 63 is, for example, a linear actuator, and moves the holding table 61 along the guide rail 64. That is, the drive mechanism 63 transfers the wafer W held on the holding table 61 between one end and the other end of the guide rail 64. Therefore, the wafer W held on the holding table 61 may be moved between a first position closer to the loading/unloading port 69 and a second position closer to the peripheral edge capturing unit 80. The guide rail 64 extends linearly (for example, straight) inside the housing 68.

The surface capturing unit 70 includes a camera 71 and an illumination module 72. The camera 71 includes a lens and a capturing element (for example, a CCD image sensor, a CMOS image sensor, or the like). The camera 71 faces the illumination module 72 in the horizontal direction. That is, the camera 71 and the illumination module 72 are arranged side by side in the horizontal direction.

The illumination module 72 includes a half mirror 73 and a light source 74. The half mirror 73 is arranged inside the housing 68 so as to be inclined at approximately 45° with respect to the horizontal direction. The half mirror 73 is located above the middle portion of the guide rail 64. The half mirror 73 has a rectangular shape and extends in a direction intersecting an extension direction of the guide rail 64 when viewed from above. A length of the half mirror 73 is set to be greater than a diameter of the wafer W.

The light source 74 is located above the half mirror 73. Light emitted from the light source 74 passes entirely through the half mirror 73 and is irradiated downward (toward the guide rail 64). The light that passes through the half mirror 73 is reflected by an object located below the half mirror 73, then reflected again by the half mirror 73, and is incident on the image sensor of the camera 71 via lens of the camera 71. That is, the camera 71 may capture an image of an object presenting in a region illuminated by the light source 74 via the half mirror 73. For example, when the holding table 61 that holds the wafer W is moved along the guide rail 64 by the drive mechanism 63, the camera 71 may capture an image of the front surface Wa of the wafer W that passes through the region illuminated by the light source 74. Data about the image obtained by the camera 71 is transmitted to the control device 100.

The peripheral edge capturing unit 80 includes a camera 81, an illumination module 82, and a mirror member 83. The camera 81 includes a lens and a capturing element (for example, a CCD image sensor, a CMOS image sensor, or the like). The camera 81 faces the illumination module 82 in the horizontal direction. That is, the camera 81 and the illumination module 82 are arranged side by side in the horizontal direction.

The illumination module 82 is disposed above the wafer W held on the holding table 61. The illumination module 82 includes a light source 84 and a half mirror 85. As shown in FIG. 5, the half mirror 85 is arranged so as to be inclined at approximately 45° with respect to the horizontal direction. As shown in FIGS. 4 and 5, the mirror member 83 is arranged below the illumination module 82. The mirror member 83 includes a main body formed of an aluminum block and a reflective surface.

When the wafer W held on the holding table 61 is at the second position, the reflective surface of the mirror member 83 faces an end surface Wb of the wafer W held on the holding table 61 and the peripheral edge region on the back surface of the wafer W. The reflective surface of the mirror member 83 is inclined with respect to a rotation axis of the holding table 61. The reflective surface of the mirror member 83 is mirror-finished. For example, a mirror sheet may be attached to the reflective surface, or the reflective surface may be aluminum-plated or vapor-deposited with an aluminum material. The reflective surface is a curved surface depressed radially outward from the wafer W held on the holding table 61.

In the illumination module 82, light emitted from the light source 84 passes entirely through the half mirror 85 and is irradiated downward. A portion of the light that passes through the half mirror 85 is reflected by the peripheral edge region of the front surface Wa of the wafer W. The reflected light does not head toward the reflective surface of the mirror member 83, but is further reflected by the half mirror 85 and then enters the capturing element of the camera 81.

On the other hand, another portion of the light that has passed through the half mirror 85 is reflected by the reflective surface of the mirror member 83 located below the half mirror 85. When the wafer W held on the holding table 61 is at the second position, the light reflected by the reflective surface of the mirror member 83 is mainly reflected by the end surface Wb of the wafer W. The reflected light is reflected sequentially by the reflective surface of the mirror member 83 and the half mirror 85, and enters the capturing element of the camera 81.

In this way, the light reflected from the peripheral edge region of the front surface Wa of the wafer W and the light reflected from the end surface Wb of the wafer W enter the capturing element of the camera 81 via different optical paths. That is, when the wafer W held on the holding table 61 is at the second position, the camera 81 is configured to capture both the peripheral edge region of the front surface Wa of the wafer W and the end surface Wb of the wafer W, thereby generating images of the peripheral edge region of the front surface Wa and the end surface Wb. Data about the images captured by the camera 81 is transmitted to the control device 100. The inspection apparatus U3 may be configured in any way as long as it is capable of capturing the peripheral edge region of the front surface Wa and generating the image of the peripheral edge region. The peripheral edge region of the front surface Wa may also be referred to as a peripheral region on the front surface Wa, and means a ring-shaped region including the peripheral edge of the front surface Wa and the vicinity of the peripheral edge. The peripheral edge capturing unit 80 may be capable of further generating the image of the end surface Wb without having to capture the peripheral edge region of the front surface Wa, and the inspection apparatus U3 may include a capturing unit capable of generating the image of the end surface Wb separately from the peripheral edge capturing unit 80. An amount of warpage of the wafer W may be measured from the image of the end surface Wb that does not include the peripheral edge region of the front surface Wa.

### <Periphery Exposure Apparatus>

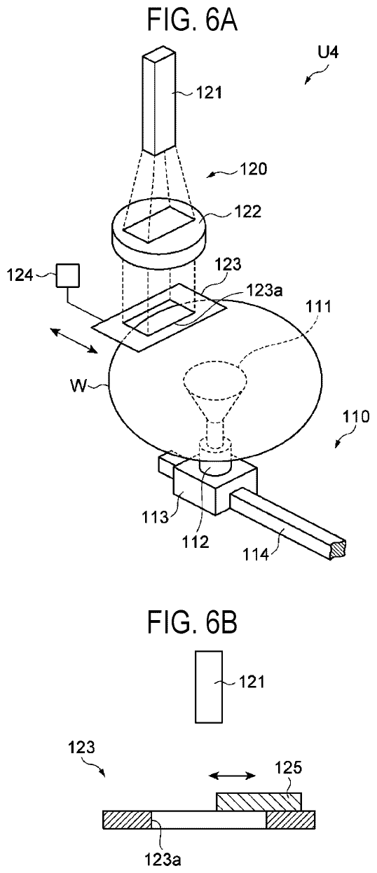

Next, the periphery exposure apparatus U4 will be described with reference to FIGS. 6A and 6B. The periphery exposure apparatus U4 (periphery exposer) is an apparatus that exposes the peripheral edge region of the front surface Wa of the wafer W. The periphery exposure apparatus U4 does not expose the region located inward of the peripheral edge region. The periphery exposure apparatus U4 includes, for example, a rotary holding unit 110 and an exposure unit 120. The rotary holding unit 110 and the exposure unit 120 are arranged inside a housing of the periphery exposure apparatus U4.

The rotary holding unit 110 is a unit that holds and rotates the wafer W. The rotary holding unit 110 includes a holding table 111 (holder), drive mechanisms 112 and 113, and a guide rail 114. The holding table 111 is, for example, a suction chuck that holds the wafer W substantially horizontally by suction or the like.

The drive mechanism 112 includes a power source such as an electric motor and rotationally drives the holding table 111. That is, the drive mechanism 112 rotates the wafer W held on the holding table 111. The drive mechanism 112 may include an encoder for detecting the rotation positions of the holding table 111. In this case, the exposure positions of the wafer W exposed by the exposure unit 120 may be associated with the rotation positions of the wafer W. The holding table 111 holds the back surface of the wafer W so that the rotational center of the wafer W rotated by the drive mechanism 112 approximately coincides with the center of the wafer W.

The drive mechanism 113 is, for example, a linear actuator, and moves the wafer W held on the holding table 111 along the guide rail 114. That is, the drive mechanism 113 transfers the wafer W held on the holding table 111 between one end and the other end of the guide rail 114. The guide rail 114 extends linearly (for example, straight) inside the housing of the periphery exposure apparatus U4. One end of the guide rail 114 is located near the exposure unit 120. When the holding table 111 holding the wafer W is at one end of the guide rail 114, the exposure unit 120 may expose the wafer W.

The exposure unit 120 is a unit that irradiates the peripheral edge region of the front surface Wa of the wafer W with exposure light. The exposure unit 120 irradiates the peripheral edge region of the front surface Wa with the exposure light while the wafer W held on the holding table 111 is rotating. The exposure unit 120 includes a light source 121, an optical system member 122, a mask member 123, and a drive mechanism 124. The light source 121 may be arranged vertically above the peripheral edge region of the front surface Wa of the wafer W arranged at an exposure position. The light source 121 irradiates downward with energy rays (for example, ultraviolet light) including wavelength components capable of exposing the resist film. The light source 121 may be, for example, an ultra-high pressure UV lamp, a high-pressure UV lamp, a low-pressure UV lamp, or an excimer lamp.

The optical system member 122 is located below the light source 121. The optical system member 122 is constituted with one or more lenses. The optical system member 122 converts the exposure light from the light source 121 into approximately parallel light and irradiates the light onto the mask member 123. The light source 121 and the optical system member 122 function as an irradiator that irradiates the exposure light. The mask member 123 has an opening 123a for adjusting an exposure area (exposure range). The parallel light from the optical system member 122 passes through the opening 123a and is irradiated onto the peripheral edge region of the front surface Wa of the wafer W held on the holding table 111. When a developing liquid is supplied to the resist film whose peripheral edge region has been irradiated with the exposure light, the region not irradiated with the exposure light is removed.

The drive mechanism 124 includes a power source such as an electric motor, and is connected to the mask member 123. The drive mechanism 124 is operated based on an operation signal from the control device 100 to move the mask member 123 along the radial direction of the wafer W. The radial direction of the wafer W is a radial direction of a circle around the center of the wafer W. When the drive mechanism 124 moves the mask member 123 along the radial direction, a radial magnitude of a range in which the exposure light reaches a portion of the resist film located in the peripheral edge region (hereinafter simply referred to as an “exposure width”) is changed.

The mask member 123 is driven by the drive mechanism 124 within a range of movement in the radial direction such that the outer edge of the front surface Wa is included in the region where the exposure light reaches the front surface Wa. In this case, the exposure width is determined by a distance in the radial direction between the outer edge of the front surface Wa and a point closest to the center of the region where the exposure light reaches the front surface Wa. Further, when the position of the mask member 123 relative to the center of the wafer W is changed in the radial direction, the radial position of the point closest to the center of the region where the exposure light reaches the front surface Wa is changed.

A method of changing the exposure width is not limited to the driving by the drive mechanism 124. The mask member 123 may include a shutter 125 as shown in FIG. 6B. FIG. 6B schematically shows a cross section cut along the radial direction of the wafer W with the optical system member 122 omitted. The shutter 125 is a member that may adjust an opening degree of an opening 123a provided in the mask member 123. The opening degree of the opening 123a means a ratio of the area that passes the exposure light from the light source 121 and the optical system member 122 to the entire area of the opening 123a.

The mask member 123 may be fixed at a position where the exposure light passing through the opening 123a reaches the outer edge of the front surface Wa and a region inside the outer edge. A drive is connected to the shutter 125. The shutter 125 is movable in the radial direction. The shutter 125 may cover a region of the opening 123a that is closer to the center of the wafer W. The opening degree of the opening 123a is changed according to a radial position of the shutter 125. As a result, the exposure width is changed. In other words, the radial position of the shutter 125 changes the radial position of the point closest to the center inside the range where the exposure light reaches the front surface Wa.

The method of changing the exposure width is not limited to the use of the drive mechanism 124 and the shutter 125. The periphery exposure apparatus U4 may change the exposure width by moving the holding table 111 that holds the wafer W along the radial direction of the wafer W relative to the mask member 123. In this case, the mask member 123 may be fixed at a predetermined position. By moving the holding table 111 (the wafer W) in the radial direction relative to the mask member 123, the ratio of the area where the exposure light that has passed through the opening 123a reaches the wafer W to the area where the exposure light does not reach the wafer W is changed when the cross section in the radial direction is observed. In other words, the radial position of the wafer W relative to the mask member 123 changes the radial position of the point closest to the center inside the range where the exposure light reaches the front surface Wa.

### <Function of Control Device>

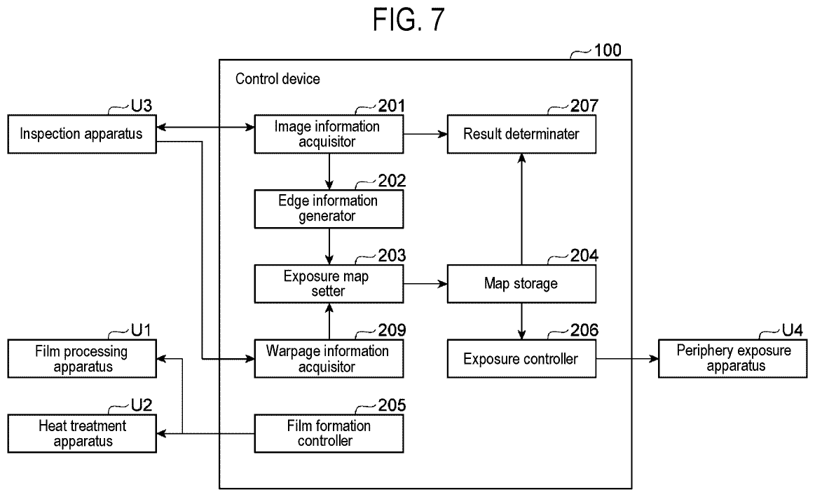

FIG. 7 is a block diagram illustrating an example of a functional configuration of the control device 100. The control device 100 includes, as its functional components (hereinafter referred to as “functional modules”), an image information acquisitor 201, an edge information generator 202, an exposure map setter 203, a map storage 204, a film formation controller 205, an exposure controller 206, and a result determiner 207. Processing performed by these functional modules corresponds to the processing performed by the control device 100.

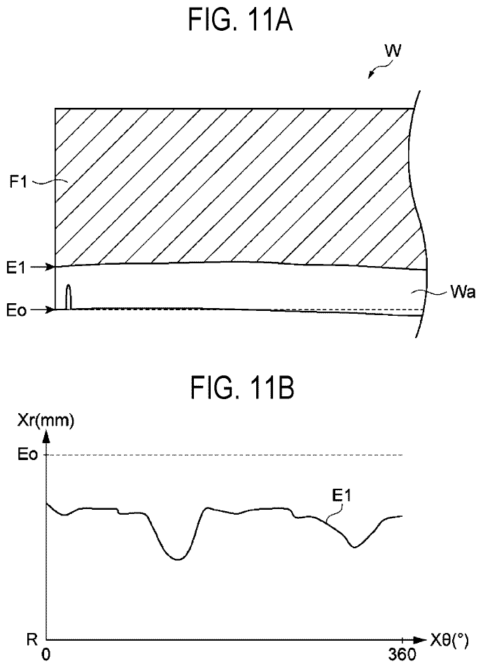

The image information acquisitor 201 is a functional module that acquires the image obtained by capturing the peripheral edge region of the front surface Wa of the wafer W with the film F1 (first film) formed on the front surface Wa. Hereinafter, the image obtained by capturing the peripheral edge region of the front surface Wa with the film F1 (first film) formed on the front surface Wa will be referred to as a “peripheral edge image” (see also FIG. 11A). The image information acquisitor 201 acquires the peripheral edge image, for example, from the inspection apparatus U3. The film F1 is a film formed below the resist film (hereinafter referred to as “film F2”) formed at least in the peripheral edge region. The film F1 may be one of a plurality of layers of films formed below the film F2. Another film may exist between the film F1 and the film F2, or the film F2 may be formed on the film F1 without providing another film therebetween.

The edge information generator 202 generates edge information indicating a relationship between the circumferential position around the center of the wafer W and the outer edge position of the film F1 in the radial direction of the wafer W, based on the peripheral edge image. The circumferential position is specified, for example, by an angle from an indicator portion (reference position) such as the notch described above. An outer edge position of the film F1 is specified, for example, by the shortest distance along the radial direction between the center of the wafer W and the outer edge of the film F1. The outer edge of the film F1 is located inward of the outer edge of the front surface Wa of the wafer W. Therefore, the outer edge position of the film F1 may be specified by the shortest distance along the radial direction between the theoretical position of the outer edge of the front surface Wa and the outer edge of the film F1.

The edge information generator 202 may calculate the outer edge position of the film F1 for each predetermined angle in the circumferential direction to generate the edge information. For example, the edge information generator 202 calculates the outer edge position of the film F1 for each arbitrary angle (for example, 1°) between 0.5° and 5°. An angle unit (for example, 1°) used when calculating the outer edge position of the film F1 may also be referred to as a resolution in the edge information. A position of the indicator portion on the wafer W may be set to 0°. The edge information generator 202 may calculate the outer edge position of the film F1 from the peripheral edge image by any image processing method.

The outer edge position of the film F1 varies according to the circumferential position, that is, the angle from the indicator portion, and various other factors. For example, missing portions depressed inward from the average outer edge position may be formed at some locations on the outer edge of the film F1. The outer edge of the film F1 may be an edge that is continuous as the circumferential position changes. That is, when the front surface Wa is viewed from above and the outer edge of the film F1 is observed in one period along the circumferential direction starting from any circumferential position on the outer edge of the film F1, no discontinuous portions are present on the outer edge of the film F1 (the outer edge of the film F1 is continuous).

The exposure map setter 203 is a functional module that sets an exposure map indicating the relationship between the circumferential position around the center of the wafer W and the set value of the exposure width in the radial direction of the wafer W based on the edge information. The exposure map setter 203 may set the exposure width for each predetermined angle in the circumferential direction in the exposure map. The exposure map setter 203 sets the exposure width for each arbitrary angle (for example, 1°) in, for example, a range of 0.5° to 5°. The angle unit (for example, 1°) when setting the exposure width may also be referred to as the resolution in the exposure map. The resolution in the edge information described above may be the same as the resolution in the exposure map.

When setting the exposure map based on the edge information, the exposure map setter 203 may set the exposure map so that the position of one end of the exposure range close to the center of the wafer W is shifted by a fixed amount from the outer edge position of the film F1 indicated by the edge information for each predetermined angle (for example, 1°) in the circumferential direction. In this case, even when the circumferential position (angle) changes, the difference between the outer edge position of the film F1 in the edge information and the position of one end of the exposure range close to the center of the wafer W remains constant. The map storage 204 is a functional module that stores the exposure map set by the exposure map setter 203.

The film formation controller 205 is a functional module that controls the film processing apparatus U1 and the heat treatment apparatus U2 to form the film F2 (the second film) on at least the peripheral edge region of the front surface Wa after the peripheral edge image is obtained. The film formation controller 205 may control the film processing apparatus U1 to form the film F2 on the entire front surface Wa, or may control the film processing apparatus U1 to form the film F2 on the peripheral edge region without forming the film F2 on the central portion including the center of the wafer W.

The exposure controller 206 is a functional module that controls the periphery exposure apparatus U4 to expose the film F2 in the peripheral edge region in accordance with the exposure map stored in the map storage 204. The exposure controller 206 controls the periphery exposure apparatus U4 to expose the film F2 in accordance with the circumferential position with the exposure width set for that circumferential position.

The exposure controller 206 may change the exposure width in accordance with the circumferential position by moving the mask member 123 using the drive mechanism 124. The exposure controller 206 may change the exposure width in accordance with the circumferential position by changing the opening degree of the opening 123a in the mask member 123 with the movement of the shutter 125. The exposure controller 206 may change the exposure width in accordance with the circumferential position by moving the holding table 111 that holds the wafer W in the radial direction.

The result determiner 207 is a functional module that determines whether or not the result of exposure in accordance with the exposure map is normal. The result determiner 207 makes a determination using an image (hereinafter referred to as a “determination image”) obtained by capturing the peripheral edge region of the front surface Wa after the exposed film F2 is developed. The determination image (second image) may be generated by the inspection apparatus U3 or may be acquired by the image information acquisitor 201. The peripheral edge image and the determination image may be acquired by the same inspection apparatus U3 or by different inspection apparatuses U3.

The result determiner 207 generates cut information indicating the relationship between the circumferential position and the inner edge position of the film F2 (the annular film F2 after development) based on the determination image. The inner edge position of the film F2 may be specified by the distance along the radial direction from the theoretical position of the outer edge of the front surface Wa. Since the film F2 is formed up to the outer edge of the front surface Wa, the inner edge position of the annular film F2 represents the exposure width. The result determiner 207 determines whether or not the exposure of the film F2 is normal based on the result of comparing either the edge information or the exposure map with the cut information.

### <Hardware Configuration of Control Device>

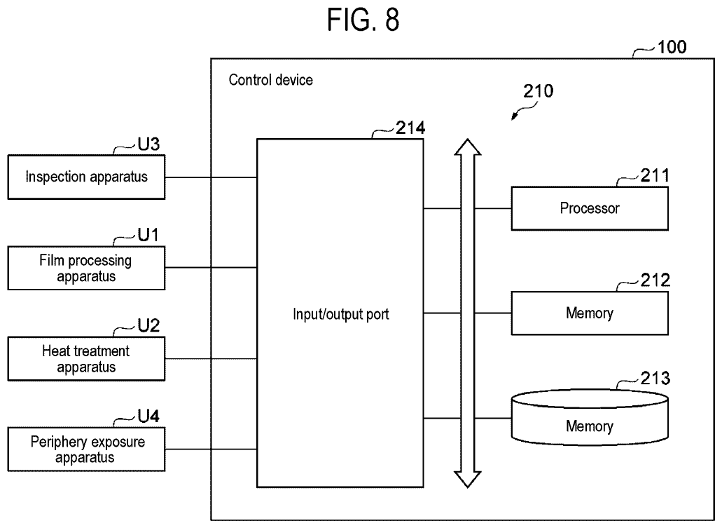

FIG. 8 shows an example of a hardware configuration of the control device 100. The control device 100 includes, for example, a circuit 210. The circuit 210 includes one or more processors 211, a memory 212, a storage 213, and an input/output port 214. The storage 213 includes a computer-readable storage medium, such as a hard disk. The storage medium stores a program for controlling the wafer processing system 1. In other words, the storage 213 (or storage medium) functions as the program storage described above. The storage medium may be a removable medium such as a non-volatile semiconductor memory, a magnetic disk, or an optical disk.

The memory 212 temporarily stores programs loaded from a storage medium of the storage 213 and calculation results obtained by the processor 211. The processor 211 executes the programs in cooperation with the memory 212, thereby configuring each functional module of the control device 100. The input/output port 214 inputs and outputs electrical signals to and from the inspection apparatus U3, the film processing apparatus U1, the heat treatment apparatus U2, the periphery exposure apparatus U4, and the like in accordance with instructions from the processor 211.

When the control device 100 is configured with a plurality of computers, each functional module may be implemented by a separate computer. Alternatively, each functional module may be implemented by a combination of two or more computers. In these cases, the plurality of computers may be connected to each other so that they may communicate with each other, and may execute control of the wafer processing system 1 in cooperation with each other. The hardware configuration of the control device 100 is not necessarily limited to one in which each functional module is configured by a program. For example, each functional module of the control device 100 may be configured by a dedicated logic circuit or an ASIC (Application Specific Integrated Circuit) that integrates such a circuit.

### [Substrate Processing Method]

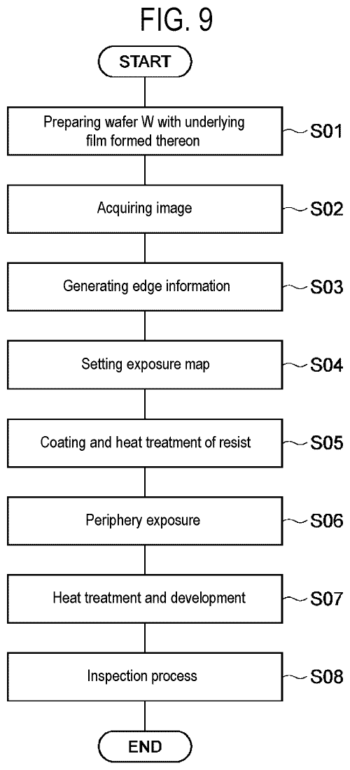

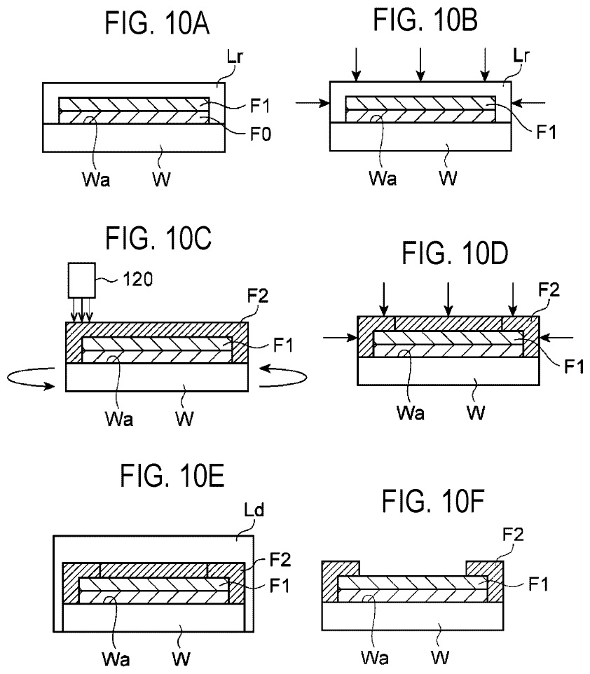

Next, an example of a substrate processing method executed in the wafer processing system 1 will be described with reference to FIGS. 9 to 14B. The following describes an example in which the film F2, which is a resist film, is formed on the peripheral edge region of the wafer W in which a concave-convex pattern has already been formed on the film F1 serving as an underlying film and the film F1 has been formed on the front surface Wa. As shown in FIG. 10A and other figures, another film F0 may be formed underneath the film F1.

The substrate processing method includes: capturing the peripheral edge region of the front surface Wa of the wafer W having the film F1 formed on the front surface Wa to obtain the peripheral edge image; and generating the edge information indicating the relationship between the circumferential position around the center of the wafer W and the outer edge position of the film F1 in a radial direction of the wafer W based on the peripheral edge image. The substrate processing method further includes: setting the exposure map indicating the relationship between the circumferential position and the set value of the exposure width in the radial direction of the wafer W based on the edge information; forming the film F2 on at least the peripheral edge region of the front surface Wa after obtaining the peripheral edge image; and exposing the film F2 in the peripheral edge region in accordance with the exposure map.

As shown in FIG. 9, first, the control device 100 executes Step S01. For example, the control device 100 controls the wafer processing system 1 to form the film F1 on the front surface Wa of the wafer W. Instead of forming the film F1 in the wafer processing system 1, the control device 100 may control the wafer processing system 1 to receive the wafer W having the film F1 formed on the front surface Wa in another processing system. The film F1 formed on the wafer W has a portion near the peripheral edge which is removed so that the outer edge of the film F1 is located inward of the outer edge of the front surface Wa. The wafer W having the film F1 formed on the front surface Wa is then transferred to the inspection apparatus U3.

Next, the control device 100 executes Step S02. In Step S02, for example, the image information acquisitor 201 causes the inspection apparatus U3 to capture an image of the peripheral edge region of the front surface Wa of the wafer W having the film F1 formed on the front surface Wa thereof, and acquires data about the image of the peripheral edge image from the inspection apparatus U3. FIG. 11A shows an example of the peripheral edge image. In the peripheral edge image shown in FIG. 11A, the circumferential position is converted to the horizontal direction on the image, and the radial direction is converted to the vertical direction on the image.

Next, the control device 100 executes Step S03. In Step S03, for example, the edge information generator 202 generates the edge information (edge profile) indicating the relationship between the circumferential position and the outer edge position of the film F1 in the radial direction from the image data obtained in Step S01. The edge information generator 202 may calculate the outer edge position of the film F1 in the radial direction from the image data obtained in Step S01 for each predetermined angle (for example, 1°) around the center of the wafer W.

FIG. 11B is a graph showing an example of the edge information. In FIG. 11B, “Xθ (°)”, which is the horizontal axis of the graph, represents the circumferential position (or angle) around the center of the wafer W. “Xr (mm)”, which is the vertical axis of the graph, represents the radial position from the center of the wafer W. “Eo” represents the theoretical radial position of the outer edge of the front surface Wa of the wafer W, and “R” represents a value obtained by subtracting a predetermined value from Eo. In one example, Eo is 150 mm, and R is any value between 140 mm and 148 mm. “E1” is information indicating the calculation result of the radial position (outer edge position) of the outer edge of the film F1.

In the edge information, for example, the outer edge position E1 of the film F1 is obtained by calculating the outer edge position of the film F1 at each circumferential position while changing the circumferential position Xθ by 1° at a time. The edge information generator 202 may calculate the outer edge position of the film F1 from, for example, the difference in pixel values between adjacent pixels on the image. The edge information generator 202 may associate the circumferential position with the outer edge position of the film F1 by specifying the position of an indicator portion formed on the wafer W on the image.

Next, the control device 100 executes Step S04. In Step S04, for example, the exposure map setter 203 sets the exposure map indicating the relationship between the circumferential position Xθ around the center of the wafer W and the set value of the exposure width in the radial direction of the wafer W, based on the edge information generated in Step S03. The set exposure map is stored in the map storage 204. The exposure map setter 203 may set the position of one end of the exposure range that is close to the center of the wafer W for each predetermined angle (for example, 1°) around the center of the wafer W, thereby setting the exposure width. As the position of the one end of the exposure range that is close to the center of the wafer W is changed, the distance between the position of the one end and the outer edge Eo of the front surface Wa is changed, and the exposure width is changed.

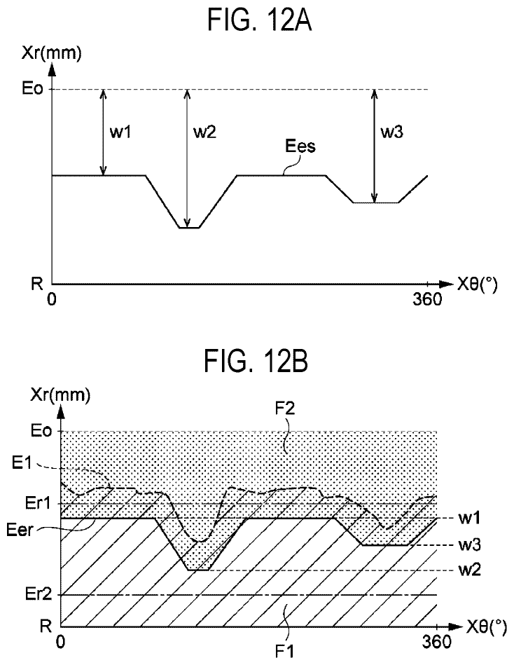

The exposure map setter 203 may set the position of one end of the exposure range that is close to the center of the wafer W for each predetermined angle so as to follow the shape of the outer edge position E1 indicated by the edge information. An example of the exposure map setting is visually shown in FIG. 12A. FIG. 12A shows a graph representing the change in the position of one end of the exposure range that is close to the center of the wafer W with respect to the circumferential position. The distance between the position of one end of the exposure range that is close to the center of the wafer W and the outer edge Eo of the front surface Wa is the exposure width, and “Ees” is information indicating the set value of the exposure width according to the circumferential position.

The exposure map setter 203 sets the exposure map (exposure width Ees) so that the tendency of change in the exposure width depending on the circumferential position follows the tendency of change depending on the circumferential position of the outer edge position of the film F1 indicated by the edge information. The exposure map setter 203 sets the exposure map, for example, so that at any circumferential position Xθ, one end of the exposure range that is close to the center of the wafer W is located inward of the outer edge of the film F1, and the difference between the one end and the outer edge of the film F1 is smaller than a predetermined value. The predetermined value may be approximately 0.5 mm to 3 mm, or may be approximately 0.5 mm to 2 mm.

By bringing the exposure map setting into conformity with the shape of the outer edge of the film F1 formed under the film F2, the exposure width setting value varies depending on the circumferential position Xθ. In the example shown in FIG. 12A, the exposure width is set to “w1” in a certain range of the circumferential position Xθ, the exposure width is set to “w2” in another certain range, and the exposure width is set to “w3” in a further certain range. The exposure width is also set in conformity with the change in the outer edge of the film F1 between two of the exposure widths w1, w2, and w3 (for example, during the change from w1 to w2).

FIG. 12B schematically shows a relationship between the annular film F2 after exposure and development and the film F1. By setting the exposure width Ees in conformity with the outer edge of the film F1, the annular film F2 after exposure and development is formed so as to cover the entire outer edge of the film F1, as shown in FIG. 12B, for example, and the inner edge shape of the film F2 is formed in conformity with the outer edge.

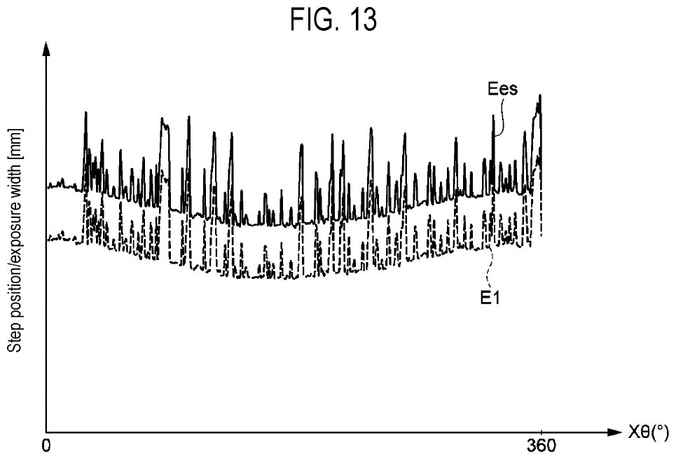

FIG. 13 shows an example of calculation results of the outer edge position of the film F1 (outer edge position E1) and the setting result of the exposure width in the exposure map (exposure width Ees) that is different from those in FIGS. 11B and 12A. Unlike FIGS. 11B and 12A, in FIG. 13, the vertical axis represents the radial distance from the outer edge Eo of the front surface Wa. As shown in FIG. 13, the exposure map setter 203 may set the exposure width so that the position of one end of the exposure range close to the center of the wafer W is shifted by a fixed amount from the outer edge position of the film F1 indicated by the edge information for each predetermined angle (for example, 1°). In this case, the difference between the exposure width Ees and the outer edge position E1 is constant at any circumferential position Xθ. In other words, the exposure width Ees is offset by a fixed amount from the outer edge position E1 throughout the entire range from 0° to 360° around the center of the wafer W. The fixed offset value may be about 0.5 mm to 5.0 mm, or about 0.5 mm to 3.0 mm.

An example of the exposure map in which the exposure width is set in increments of 1° is shown in Table 1 below. The exposure map shown in Table 1 is provided as an example to facilitate understanding of the contents of the present disclosure.

TABLE 1

| | Xθ | Exposure |
|---|---|---|
| Step | (°) | width (mm) |
| 1 | 1 | 1.1 |
| 2 | 2 | 1.2 |
| 3 | 3 | 1.1 |
| 4 | 4 | 1.2 |
| 5 | 5 | 1.0 |
| . | . | . |
| . | . | . |
| . | . | . |
| 359 | 359 | 1.1 |

Returning to FIG. 9, the control device 100 then executes Step S05. Before Step S05, the wafer W with the film F1 formed thereon is transferred from the inspection apparatus U3 to the film processing apparatus U1. In Step S05, for example, the film formation controller 205 controls the film processing apparatus U1 to apply the processing liquid Lr to the entire front surface Wa of the wafer W, as shown in FIG. 10A. After the wafer W is transferred to the heat treatment apparatus U2, the film formation controller 205 controls the heat treatment apparatus U2 to heat the coated film of the processing liquid Lr, as shown in FIG. 10B. As a result, the film F2 before exposure and development is formed on the entire front surface Wa. The wafer W is then transferred from the heat treatment apparatus U2 to the periphery exposure apparatus U4.

Next, the control device 100 executes Step S06. In Step S06, for example, the exposure controller 206 controls the periphery exposure apparatus U4 to expose the film F2 in the peripheral edge region of the front surface Wa in accordance with the exposure map set in Step S04. As shown in FIG. 10C, the exposure controller 206 causes the exposure unit 120 to irradiate the peripheral edge region of the front surface Wa with exposure light while rotating the wafer W held on the holding table 111 by the rotary holding unit 110. The exposure controller 206 controls the periphery exposure apparatus U4 so that exposure of the film F2 is performed with the set exposure width for each angle for which the exposure width is set in the exposure map.

Using the example shown in Table 1, the exposure controller 206 controls the periphery exposure apparatus U4 so that the exposure width is 1.1 mm at the location where the circumferential position Xθ is 1° and so that the exposure width is 1.2 mm at the location where the circumferential position Xθ is 2°. The exposure controller 206 may continue irradiating the wafer W with exposure light by the exposure unit 120 while continuing the rotation of the wafer W without stoppage thereof. In this case, the exposure controller 206 moves the mask member 123 using the drive mechanism 124 so that the exposure width is changed from 1.1 mm to 1.2 mm, for example, while the circumferential position Xθ transitions from 1° to 2°. The exposure controller 206 may change the speed of movement of the mask member 123 depending on the change in the exposure width between two consecutive operations in the exposure map. After the peripheral edge region of the film F2 is exposed in accordance with the exposure map, the wafer W is transferred from the periphery exposure apparatus U4 to the heat treatment apparatus U2.

Next, the control device 100 executes Step S07. In Step S07, for example, as shown in FIG. 10D, the film formation controller 205 controls the heat treatment apparatus U2 to perform a pre-development heat treatment on the wafer W (the film F2). After the pre-development heat treatment, the wafer W is transferred from the heat treatment apparatus U2 to the film processing apparatus U1 where development is performed.

Then, as shown in FIG. 10E, the film formation controller 205 controls the film processing apparatus U1 to supply a developing liquid Ld to the front surface Wa to develop the film F2. This removes the portions of the film F2 that are not irradiated with the exposure light. Thereafter, as shown in FIG. 10F, the developing liquid Ld is washed away, thereby forming a ring-shaped film F2 in the outer peripheral region of the front surface Wa. After the development, the wafer W is transferred from the film processing apparatus U1 to the inspection apparatus U3.

Next, the control device 100 executes Step S08. In Step S08, for example, the result determiner 207 executes an inspection process regarding the exposure of the film F2. In one example, the result determiner 207 uses the inspection apparatus U3 to capture the peripheral edge region of the wafer W after exposure and development, and acquires image data for the inspection process (the above-mentioned determination image) from the inspection apparatus U3. The result determiner 207 generates cut information indicating the relationship between the circumferential position Xθ and the inner edge position of the film F2 in the radial direction of the wafer W from the image data for the inspection process. The result determiner 207 may calculate the inner edge position of the film F2 in the radial direction of the wafer W from the image data for the inspection process for each predetermined angle (for example, 1°) around the center of the wafer W.

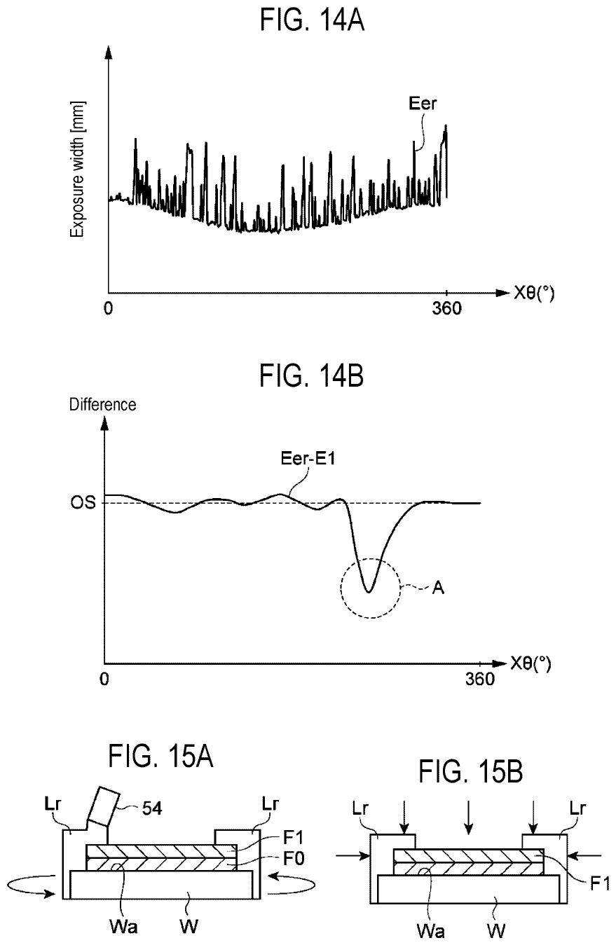

FIG. 14A is a graph showing an example of the cut information. In FIG. 14A, the vertical axis represents the radial distance between the outer edge Eo of the front surface Wa and the inner edge position of the film F2, that is, the radial width of the film F2. “Eer” is information showing the calculation result of the radial position (inner edge position) of the inner edge of the film F2. When the periphery exposure in accordance with the exposure map is normal, the inner edge position Eer will either approximately coincide with the exposure width Ees shown in FIG. 13 or be offset by a predetermined value from the outer edge position E1 of the film F1 at any circumferential position Xθ. Therefore, the result determiner 207 may determine whether or not the result of the periphery exposure is normal by comparing the exposure width Ees with the inner edge position Eer. Further, the result determiner 207 may determine whether or not the result of the periphery exposure is normal by comparing the outer edge position E1 with the inner edge position Eer.

In one example, the result determiner 207 calculates a difference between the inner edge position Eer and the outer edge position E1 for each predetermined angle (for example, 1°) around the center of the wafer W. FIG. 14B is a graph showing the difference obtained by subtracting the outer edge position E1 from the inner edge position Eer. When the constant value offset from the outer edge position E1 is assumed to be “OS,” when the periphery exposure is normal, the difference between the inner edge position Eer and the outer edge position E1 will be approximately constant regardless of the circumferential position Xθ.

On the other hand, when an abnormality occurs at a certain location due to a certain factor, the difference between the inner edge position Eer and the outer edge position E1 will deviate from the offset constant value (OS), as shown in the portion indicated by “A” in FIG. 14B. In this case, the result determiner 207 may determine that exposure is not performed normally in the portion indicated by “A.” By looking at the difference between the outer edge position E1 (actual value) and the inner edge position Eer (actual value) rather than the difference between the exposure width Ees (set value) and the inner edge position Eer (actual value), it is possible to confirm whether or not the inner edge position of the film F2 has been offset.

The control device 100 also executes the series of processes of Steps S01 to S08 for each of the subsequent wafers W. The shape (state) of the outer edge of the film F1 is likely to differ for each individual wafer W. By repeating the series of processes described above, an exposure map tailored to each individual wafer W may be set.

### Modifications

The series of processes shown in FIG. 9 is an example and may be modified as appropriate. In the series of processes described above, the control device 100 may execute one step and the next step in parallel, or may execute the respective operations in an order different from that of the example described above. The control device 100 may also execute operations having contents different from those of the example described above.

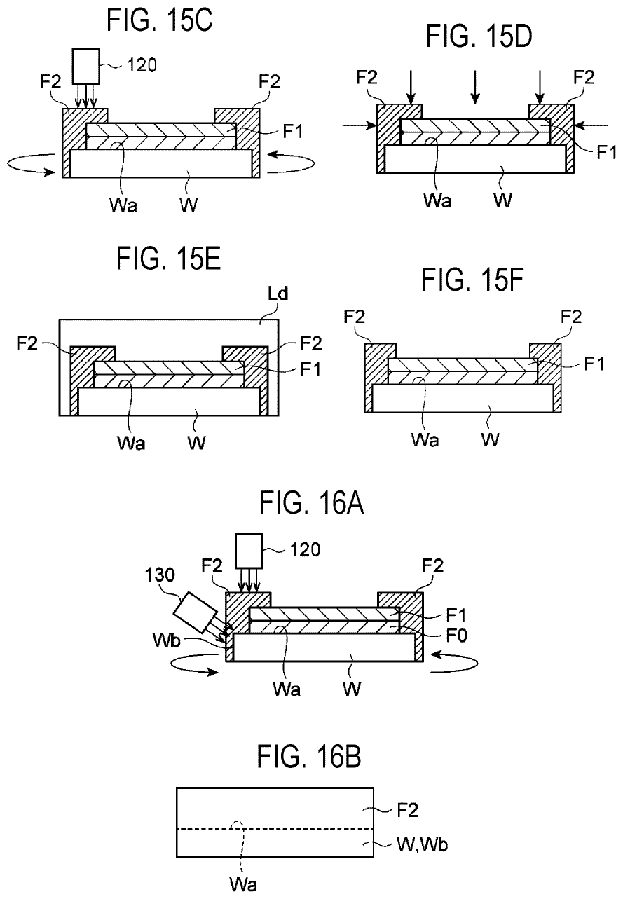

In the above example, the processing liquid Lr is applied to the entire front surface Wa when forming the film F2 before exposure and development. However, the processing liquid Lr does not have to be applied to the central portion of the front surface Wa. FIGS. 15A to 15F show examples of a substrate processing method in which a coated film of the processing liquid Lr is formed only in the peripheral edge region of the front surface Wa. The operations shown in FIGS. 15A to 15F correspond to the operations shown in FIGS. 10A to 10F, respectively.

As shown in FIG. 15C, an annular film F2 is formed in and near the peripheral edge region of the front surface Wa. The inner edge of the film F2 is formed so as to be located more inward than the outer edge of the film F1. The film F2 is then subjected to periphery exposure by the periphery exposure apparatus U4 equipped with the exposure unit 120. By exposing and developing the film F2, the unexposed portion of the annular film F2 (the portion located on the inner side) is removed. In the heat treatment shown in FIGS. 15B and 15D, heat may be applied only to the peripheral edge region of the wafer W without applying heat to the central portion of the wafer W.

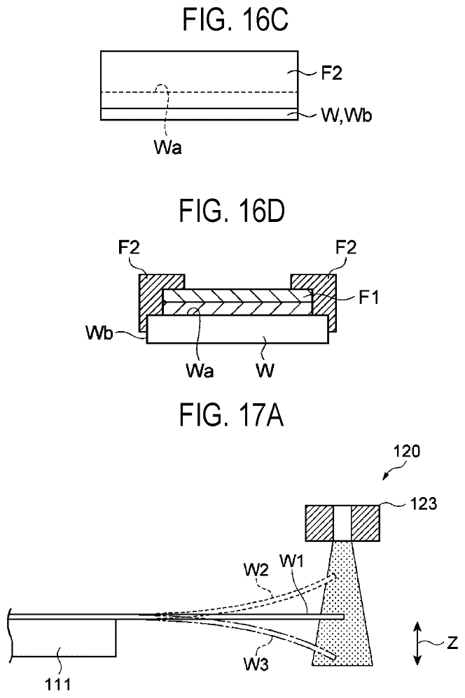

As shown in FIG. 16A, the film F2 before exposure and development may be formed to cover not only the front surface Wa of the wafer W but also the end surface Wb thereof. The periphery exposure apparatus U4 may have an exposure unit 130 capable of exposing the end surface Wb in addition to the exposure unit 120. FIG. 16B schematically shows the film F2 on the end surface Wb before exposure and development, and FIG. 16C schematically shows the film F2 on the end surface Wb after exposure and development. FIG. 16D schematically shows the film F2 after exposure and development. As shown in FIGS. 16C and 16D, a portion of the film F2 may be removed from the lower portion of the end surface Wb by exposure and development.

As described above, the inspection apparatus U3 may capture an image the end surface Wb in addition to the peripheral edge region of the front surface Wa. Therefore, the control device 100 may detect the condition of the base on the end surface Wb from the image of the end surface Wb. The exposure controller 206 may then perform exposure on the end surface Wb using the exposure unit 130 in accordance with the condition of the base on the end surface Wb. For example, the height of the region onto which the exposure light from the exposure unit 130 is applied may be adjusted in conformity with the condition of the base on the end surface Wb in accordance with the circumferential position Xθ.

In the above-described example, the inner edge of the film F2 after exposure and development is located inward of the outer edge of the film F1, and the film F2 is formed so as to follow the shape of the outer edge of the film F1. Alternatively, the inner edge of the film F2 after exposure and development may be located outward of the outer edge of the film F1, and the film F2 may be formed so as to follow the shape of the outer edge of the film F1.

In the above example, the negative resist material is used. However, a positive resist material may also be used to form the film F2. In this case, for example, the film F2 before exposure and development is formed over the entire front surface Wa. Thereafter, the periphery exposure apparatus U4 exposes the peripheral edge region of the film F2 with an exposure width corresponding to the position of the outer edge of the film F1. Then, the exposed portions are removed by development, so that the peripheral edge region of the film F2 is removed. The outer edge of the film F2 after exposure and development may be located outward or inward of the outer edge of the film F1, as long as it follows the shape of the outer edge of the film F1.

When the positive resist material is used, the result determiner 207 generates cut information indicating the relationship between the circumferential position and the outer edge position of the film F2 (the film F2 from which the peripheral edge portion is removed after development) based on the determination image. The outer edge position of the film F2 may be specified by the radial distance from the theoretical position of the outer edge of the front surface Wa. Since the film F2 before development and exposure is exposed up to the outer edge of the front surface Wa, the outer edge position of the film F2 after the peripheral edge portion is removed represents the exposure width. As in the case where the negative resist material is used, the result determiner 207 determines whether or not the exposure of the film F2 is normal based on the result of comparing either the edge information or the exposure map with the cut information.

The image information acquisitor 201 may acquire a peripheral edge image obtained by capturing the peripheral edge region of the front surface Wa from an external device separate from the substrate processing system, instead of the inspection apparatus U3.

When changing the exposure width by driving the mask member 123 or the like in accordance with the exposure map, the exposure controller 206 may change the exposure width while stopping the rotation of the wafer W by the drive mechanism 112 of the rotary holding unit 110. For example, when an exposure map such as that shown in Table 1 is obtained, the exposure controller 206 may control the periphery exposure apparatus U4 so that exposure is performed with an exposure width (1.1 mm) associated with 1° when the circumferential position Xθ (angle) is in the range of 1° to 2°. Then, the exposure controller 206 may stop the rotation of the wafer W before the exposure light is irradiated onto a location where the circumferential position Xθ is 2°, and may change the position of the mask member 123 or the like in conformity with the exposure width (1.2 mm) associated with 2°.

The exposure map may be set as shown in Table 2 below.

TABLE 2

| | Processing | Exposure | Start | Angle |
|---|---|---|---|---|
| | time | width | angle | range |
| Step | (sec) | (mm) | (°) | (°) |
| 1 | 0.5 | 1.1 | 0 | 1 |
| 2 | 0.5 | 1.2 | 1 | 1 |
| 3 | 0.5 | 1.1 | 2 | 1 |
| 4 | 0.5 | 1.2 | 3 | 1 |
| 5 | 0.5 | 1.0 | 4 | 1 |
| . | . | . | . | . |
| . | . | . | . | . |
| . | . | . | . | . |
| 359 | 0.5 | 1.1 | 358 | 1 |

The exposure map shown in Table 2 indicates that the processes from “step 1” to “step 359” are executed in order, and the conditions for each step are set as a processing time (sec), an exposure width (mm), a start angle (°), and an angle range (°). The processing time indicates the execution time of the step, and the exposure width is the radial exposure range set based on the edge information. The start angle indicates the circumferential position Xθ (angle) at which the step is executed, and the angle range indicates the circumferential range over which the step continues. For example, step 1 indicates that the processing continues for 0.5 seconds with the exposure width adjusted to 1.1 mm when the circumferential position Xθ is in the range from 0° to 1°. Several examples of control in accordance with the exposure map shown in Table 2 will be described below.

### Example 1

The exposure controller 206 may change the exposure width by driving the mask member 123 or the like while continuing to rotate the wafer W so that one step and a subsequent step are executed consecutively. When the exposure width has changed from the previous step, the exposure controller 206 may start driving the mask member 123 or the like to change the exposure width at the start of the current step. Driving the mask member 123 or the like means driving the mask member 123 to change the exposure width, driving the shutter 125 to change the exposure width, or driving the holding table 111 to change the exposure width. The exposure controller 206 may control the drive mechanism 112 that rotates the holding table 111 so that the wafer W rotates at a constant rotational speed in all operations. In all operations, the exposure unit 120 may irradiate the exposure portion on the front surface Wa of the wafer W with exposure light having a constant illuminance.

### Example 2

In the exposure map, the exposure width and the rotation speed of the wafer W may be set for each predetermined angle. When exposing the film F2, the exposure controller 206 may change the exposure width while continuing to rotate the wafer W in accordance with the exposure map, and irradiate the front surface Wa with exposure light using the exposure unit 120. In setting the exposure map, the exposure map setter 203 may repeatedly evaluate the difference in exposure width between two consecutive angles while changing the angle one by one. Here, one of the two angles to be evaluated at which exposure light is first irradiated is defined as a “first angle,” and the other angle consecutive to the first angle is defined as a “second angle.” The exposure map setter 203 may repeatedly calculate the difference between the exposure width at the first angle and the exposure width at the second angle consecutive to the first angle while changing the second angle by the predetermined angle. When the condition that the difference (the difference in exposure width between the first angle and the second angle) is smaller than a predetermined level is satisfied in a range that includes a predetermined number or more consecutive angles, the exposure map setter 203 may set the rotation speed in that range to a value greater than a speed reference value. Each of the predetermined level and the predetermined number is arbitrarily set in advance when the exposure map is set.

In one example, after creating an exposure map such as that shown in Table 2, the exposure map setter 203 repeatedly calculates the difference between the exposure width at a target step (the exposure width at the second angle) and the exposure width at the step immediately before the target step (the exposure width at the first angle) while incrementing the target step by one. Specifically, the exposure map setter 203 calculates the difference between the exposure width at step 1 and the exposure width at step 2, and then calculates the difference between the exposure width at step 2 and the exposure width at step 3. Thereafter, the exposure map setter 203 repeatedly calculates the difference in exposure width between two consecutive operations in a similar manner.

When the condition that the difference in exposure width between two consecutive operations is equal to or less than a predetermined level is satisfied in a range that includes a predetermined number (for example, 3 to 7) or more consecutive target operations, the exposure map setter 203 sets the rotation speed to a value greater than the reference speed value in the range that includes the predetermined number or more target operations. To explain this using a specific example, it is assumed that, when the predetermined number is 5, in the range of operations 2 to 6, the difference in exposure width from the previous step is within a predetermined level (for example, ±0.3 mm), and the difference in exposure width between operations 6 and 7 is greater than the predetermined level. In this case, the exposure map setter 203 sets the rotation speed in the range of operations 2 to 6 to a value (for example, 12 rpm) greater than the reference speed value (for example, 10 rpm). When the predetermined number is 5, when the condition is satisfied in six or more consecutive operations, the rotation speed in the six or more operations is set to a value greater than the reference speed value.

The exposure map setter 203 may set the rotation speed to the speed reference value (or less than the speed reference value) for operations (angles) outside the range in which the rotation speed is set to a value greater than the speed reference value. Depending on the setting of the exposure width in the exposure map, there may not be a predetermined number of consecutive operations that satisfy the above conditions. In this case, the exposure map setter 203 may set the rotation speed to the speed reference value (or less than the speed reference value) in each of all operations.

### Example 3

As in Example 2 described above, when the rotation speed is increased over a range in which the variation in the exposure width is continuously small, the exposure map may further set the illuminance of the exposure light for each predetermined angle. When exposing the film F2, the exposure controller 206 may control the exposure unit 120 to irradiate the front surface Wa with the exposure light while adjusting the illuminance in accordance with the exposure map. In this case, the exposure unit 120 may be configured to adjust the illuminance of the exposure light (the dose in the region irradiated by the exposure light). The dose in the region irradiated by the exposure light on the front surface Wa is changed depending on the illuminance of the exposure light.

When setting the exposure map, the exposure map setter 203 may set the illuminance of the exposure light to a value greater than the illuminance reference value in a range where the rotation speed of the wafer W is set to a value greater than the speed reference value. To explain using a specific example, in the exposure map such as that shown in Table 2, when the rotation speed is set to a value greater than the speed reference value in the range of operations 2 to 6, the illuminance in each of operations 2 to 6 is set to a value greater than the illuminance reference value. When there are no consecutive operations that satisfy the above conditions, the exposure map setter 203 may set the illuminance of the exposure light to the illuminance reference value (or less than the illuminance reference value) in each of all operations.

### Example 4

In addition to or instead of the setting in Example 2 described above, the exposure map setter 203 may set the rotation speed at an angle (second angle) that satisfies the condition that the difference between the exposure width at the first angle and the exposure width at the second angle subsequent to the first angle is greater than a predetermined level, to a value smaller than the speed reference value. In Example 4, the exposure map setter 203 also repeatedly calculates the difference between the exposure width at the first angle and the exposure width at the second angle subsequent to the first angle while changing the second angle by the above-mentioned predetermined angle. The predetermined level used in Example 4 may be different from the predetermined level used in Example 2 and is arbitrarily set in advance at the time of setting the exposure map.

In one example, the exposure map setter 203 creates an exposure map such as that shown in Table 2, and then repeatedly calculates the difference between the exposure width at a target step (the exposure width at the second angle) and the exposure width at the step immediately preceding the target step (the exposure width at the first angle) while increasing the target step by 1. Then, the exposure map setter 203 sets the rotation speed to a value smaller than the speed reference value in a target step that satisfies the condition that the difference in exposure width between two consecutive operations is greater than a predetermined level.

To explain this using a specific example, it is assumed that the difference in exposure width between step 5 and the previous step 4 is greater than a predetermined level (for example, ±0.5 mm). In this case, the exposure map setter 203 sets the rotation speed in step 5 to a value (for example, 5 rpm) smaller than the speed reference value (for example, 10 rpm). The exposure map setter 203 may set the rotation speed to the speed reference value (or a value greater than the speed reference value) for a step (angle) outside the range in which the rotation speed is set to a value smaller than the speed reference value. Depending on the exposure width setting in the exposure map, there may be no step that satisfies the above condition in Example 4. In this case, the exposure map setter 203 may set the rotation speed to the speed reference value (or a value greater than the speed reference value) in each of all operations.

### Example 5

As in Example 4 described above, when the rotation speed is reduced in a portion where the exposure width fluctuates rapidly, the exposure map may further set the illuminance of the exposure light for each predetermined angle. When exposing the film F2, the exposure controller 206 may control the exposure unit 120 to irradiate the front surface Wa with the exposure light while adjusting the illuminance in accordance with the exposure map. In this case, the exposure unit 120 may be configured to be able to adjust the illuminance of the exposure light (the dose in the region irradiated by the exposure light).

When setting the exposure map, the exposure map setter 203 sets the illuminance of the exposure light to a value smaller than the illuminance reference value at one or more angles where the rotation speed of the wafer W is set to a value smaller than the speed reference value. To explain using a specific example, in the exposure map such as that shown in Table 2, when the rotation speed is set to a value smaller than the speed reference value in step 5, the illuminance in step 5 is set to a value smaller than the illuminance reference value. When there is no step that satisfies the above condition in Example 4, the exposure map setter 203 may set the illuminance of the exposure light to the illuminance reference value (or a value greater than the illuminance reference value) in each of all operations.

### Example 6

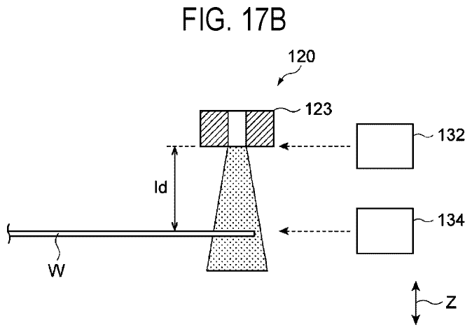

Periphery exposure on the front surface Wa of the wafer W may be performed, depending on the state of warpage on the front surface Wa of the wafer W while adjusting the position of the mask member 123 in the direction in which the exposure light is emitted. FIG. 17A shows a schematic diagram for explaining the issues that arise when the wafer W includes warpage. In FIG. 17A, a wafer W with no warpage (flat) in the exposure target portion of the peripheral edge region is indicated by “W1,” a wafer W warped so that the exposure target portion of the peripheral edge region curved upward is indicated by “W2,” and a wafer W warped so that the exposure target portion of the peripheral edge region curved downward is indicated by “W3.” There may be a case where a single wafer W has a mixture of two or more of the characteristics of a non-warped portion, an upwardly curved portion, and a downwardly curved portion.

In FIG. 17A, the region with many dots represents the range of light irradiated from the opening of the mask member 123. The range of light irradiated from the opening of the mask member 123 expands as the light travels, even when the optical path is adjusted by the optical system member 122. When the position of the mask member 123 is fixed, the distance in the Z-axis direction between the mask member 123 and the exposure target portion on the front surface Wa (hereinafter referred to as an “irradiation distance Id”) (see FIG. 17B) differs among the wafers W1, W2, and W3. When the irradiation distances Id differ from one another, the actual exposed width will change even when the exposure width setting remains the same.

As shown in FIG. 7, the control device 100 may include a warpage information acquisitor 209 as a functional block. The warpage information acquisitor 209 acquires information indicating the state of warpage in the peripheral edge region of the front surface Wa of the wafer W (hereinafter simply referred to as “warpage information”). The warpage information acquisitor 209 acquires an end surface image of the end surface Wb of the wafer W, for example, from the inspection apparatus U3, and acquires warpage information from the difference between the wafer W and a reference wafer that has no warpage. The warpage information may be information indicating the relationship between the circumferential position Xθ around the center of the wafer W and the amount of warpage in the outer edge portion of the front surface Wa of the wafer W.

When generating the warpage information, the warpage information acquisitor 209 may calculate the amount of warpage of the outer edge portion of the front surface Wa for each predetermined angle in the circumferential direction. The warpage information acquisitor 209 calculates the amount of warpage of the outer edge portion of the front surface Wa for each arbitrary angle (for example, 1°) between 0.5° and 5°, for example. The angle unit (for example, 1°) used to calculate the amount of warpage of the outer edge portion of the front surface Wa may also be referred to as the resolution of the warpage information. The resolution of the warpage information may be the same as the resolution of the exposure map.

The drive mechanism 124 connected to the mask member 123 may change the position of the mask member 123 in the Z-axis direction. The mask member 123 having the shutter 125 may be raised and lowered by the drive mechanism connected to the mask member 123. The exposure map may set the position of the mask member 123 for each predetermined angle in the direction in which the exposure light is emitted. The exposure controller 206 may control the exposure unit 120 (for example, the drive mechanism 124) to irradiate the front surface Wa with the exposure light while adjusting the position of the mask member 123 in the direction in which the exposure light is emitted in accordance with the exposure map. The direction in which the exposure light is emitted from the opening 123a of the mask member 123 may be the Z-axis direction. That is, the opening 123a (a plane including the edge of the opening 123a) may be orthogonal to the Z-axis direction.

In setting the exposure map, the exposure map setter 203 may set the position of the mask member 123 in the direction in which the exposure light is emitted for each predetermined angle based on the warpage information. The exposure map setter 203 may set the position of the mask member 123 in the Z-axis direction according to the amount of warpage indicated by the warpage information so that the difference in the irradiation distance Id for each angle is reduced (for example, so that the irradiation distance Id is constant). The position of the mask member 123 in the Z-axis direction may be specified by a difference from a reference position (that is, an offset value).

As shown in FIG. 17B, the periphery exposure apparatus U4 may include a position sensor 132 and a position sensor 134. The position sensor 132 is a sensor that acquires information indicating the position of the mask member 123 in the Z-axis direction. The position sensor 132 acquires, for example, information indicating the position of the lower surface of the mask member 123 in the Z-axis direction. The position sensor 134 is a sensor that acquires information indicating the position of the peripheral edge portion (exposure target portion) of the front surface Wa of the wafer W in the Z-axis direction. The irradiation distance Id may be calculated based on the position information acquired by the position sensors 132 and 134. The position sensors 132 and 134 may be of any type as long as they may detect information indicating a position, but may be, for example, non-contact position sensors.

The control device 100 may acquire information from the position sensors 132 and 134 while controlling the periphery exposure apparatus U4 to expose the film F2 in the peripheral edge region of the front surface Wa in accordance with the exposure map. The control device 100 may then evaluate whether or not the irradiation distance Id during exposure of the film F2 in the peripheral edge region is within an appropriate range based on the information from the position sensors 132 and 134. The control device 100 may issue an alarm when it evaluates that the irradiation distance Id during exposure is not within the appropriate range.

When comparing the magnitude relationship of two numerical values within a computer, either of the two criteria “greater than or equal to” and “greater than” may be used, or either of the two criteria “equal to or less than” and “less than” may be used. The selection of such criteria does not change the technical significance of the process of comparing the magnitude relationship of two numerical values. In one of the various examples described above, at least some of the matters described in another example may be combined.

### <Modification of Periphery Exposure Apparatus>

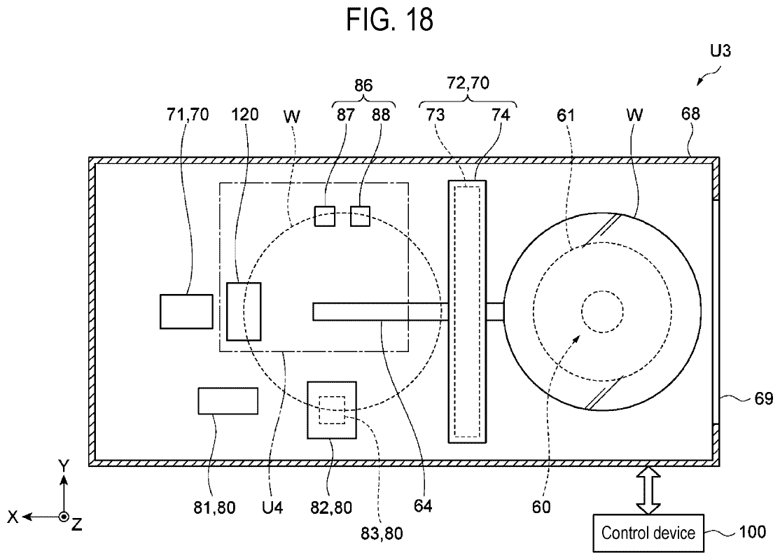

Next, a modification of the periphery exposure apparatus U4 will be described. As shown in FIG. 18, the periphery exposure apparatus U4 may be located within the housing of the inspection apparatus U3. When the configuration of the exposure unit 120 is located within the region indicated by the one-dot chain line in FIG. 18, the configuration shown in FIGS. 6A and 6B above that has the same functions as the configuration shown in FIGS. 4 and 5 may be implemented by the configuration shown in FIGS. 4 and 5. For example, the rotary holding unit 110, the holding table 111 (holder), the drive mechanisms 112 and 113, and the guide rail 114 shown in FIGS. 6A and 6B correspond to the rotary holding unit 60, the holding table 61, the drive mechanisms 62 and 63, and the guide rail 64 shown in FIGS. 4 and 5 (FIG. 18). When operating as the periphery exposure apparatus U4, the holding table 61 (holder) is moved by the drive mechanism 63 to the second position closer to the exposure unit 120. After the movement, the wafer W held on the holding table 61 may be exposed.

As shown in FIG. 18, the inspection apparatus U3 including the periphery exposure apparatus U4 may include a state detector 86 that detects the state of the wafer W held on the support table 61 before periphery exposure. The state detector 86 includes a peripheral-end-portion measurement sensor 87 that measures the position of the peripheral end portion of the wafer W held on the support table 61 and a distance sensor 88 that measures the distance in the Z-axis direction (vertical direction) from the front surface Wa of the wafer W) to the outer edge of the wafer W. The peripheral-end-portion measurement sensor 87 is a sensor that measures the horizontal position of the peripheral end portion of the wafer W, and includes, for example, a CCD camera. The peripheral-end-portion measurement sensor 87 is used to calculate the amount of eccentricity from the center position of the wafer W and to detect the position of a notch in the wafer W. The distance sensor 88 measures the distance to the outer edge of the wafer W in the Z-axis direction. The distance sensor 88 may be, for example, a photoelectric sensor or an ultrasonic sensor. The peripheral-end-portion measurement sensor 87 and the distance sensor 88 may be configured to measure the position and distance of the wafer W from the back surface of the wafer W, so as not to affect the film on the front surface of the wafer W.

The warpage information acquisitor 209 of the control device 100 shown in FIG. 7 may acquire information indicating the state of warpage in the peripheral edge region of the front surface Wa of the wafer W based on the measurement results of the peripheral-end-portion measurement sensor 87 and the distance sensor 88. The warpage information acquisitor 209 may acquire information indicating the state of warpage based on the values of the peripheral-end-portion measurement sensor 87 and the distance sensor 88 for each predetermined angle (for example, any angle between 0.5° and 5°) of the outer edge of the wafer W.

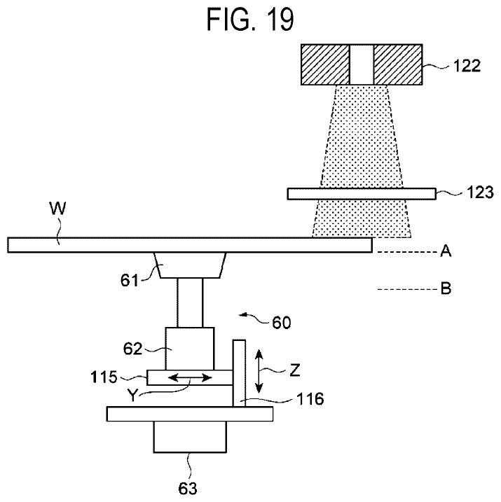

FIG. 19 shows another example of the structure of the rotary holding unit 60 of the periphery exposure apparatus U4 described in FIG. 18. In FIG. 19, a Y-axis direction adjuster 115 (radial direction adjuster) and a Z-axis direction adjuster 116 (vertical direction adjuster) are provided above the drive mechanism 63. The drive mechanism 62 is connected to the upper portion of the Y-axis direction adjuster 115, and the Z-axis direction adjuster 116 is connected to the side portion thereof. The Y-axis direction adjuster 115 includes a drive (not shown) that operates in response to an operation signal from the control device 100 to adjust the positions of the support table 61 and the drive mechanism 62 in the Y-axis direction (the radial direction of the wafer W). The Z-axis direction adjuster 116 includes a drive (not shown) that operates in response to an operation signal from the control device 100 to adjust the positions of the support table 61 and the drive mechanism 62 in the Z-axis direction (the vertical direction from the front surface of the wafer W).

Although not shown in FIG. 19, the mask member 123 may be provided with a drive that adjusts the position in the Z-axis direction. The drive of the mask member 123 may be operated in response to an operation signal from the control device 100, thereby changing the position of the mask member 123 in the Z-axis direction.

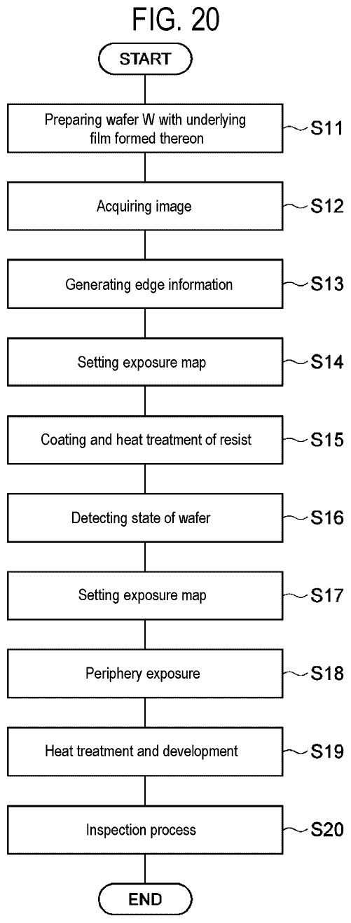

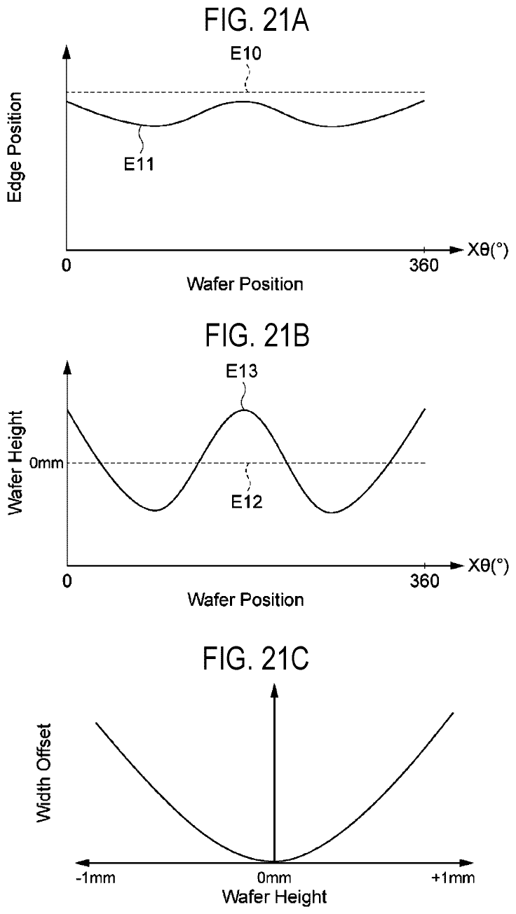

Referring to FIG. 20 and FIGS. 21A to 21C, an example of a wafer processing method executed in the wafer processing system 1 will be described. The processes from Step S11 to Step S15 are similar to the processes from Step S01 to Step S05 in FIG. 9, and therefore will not be described again. After Step S15, the control device 100 executes Step S16. For example, in Step S16, the control device 100 controls the drive mechanism 63 to move the support table 61 holding the wafer W to the second position closer to the exposure unit 120. After the movement, the control device 100 rotates the support table 61 and causes the state detector 86 to detect the state of the wafer W held on the support table 61. The peripheral-end-portion measurement sensor 87 of the state detector 86 measures the position of the peripheral end portion of the wafer W for each predetermined angle (for example, 1°). The distance sensor 88 measures the distance to the outer edge of the wafer W in the Z-axis direction for each predetermined angle (for example, 1°). Although the angle is described as, for example, 1°, it may be equal to or greater than 1° or equal to or less than 1° (for example, 0.5°). The warpage information acquisitor 209 acquires information for each measured angle.

Next, the control device 100 executes Step S17. In Step S17, for example, the exposure map setter 203 sets an exposure map based on the measurement values obtained in Step S16. The exposure map setter 203 sets an exposure map based on the distance to the outer edge of the wafer W in the Z-axis direction for each predetermined angle and the position of the peripheral end portion of the wafer W for each predetermined angle. The exposure map may adjust position information of the wafer W during periphery exposure, that is, the radial position of the wafer W and the Z-axis position of the mask, for each angle (for example, 1°) in the circumferential direction of the wafer W.

The exposure map may be set as shown in Table 3 below.

TABLE 3

| | | | | | Mask |
|---|---|---|---|---|---|
| | | | | Wafer | height |
| | Processing | Exposure | Start | adjustment | adjustment |
| | time | width | angle | position | value |
| Step | (sec) | (mm) | (°) | (mm) | (mm) |
| 1 | 0.5 | 1.1 | 0 | +0.01 | +0.5 |
| 2 | 0.5 | 1.2 | 1 | +0.02 | +0.4 |
| 3 | 0.5 | 1.4 | 2 | +0.02 | +0.5 |
| 4 | 0.5 | 1.0 | 3 | +0.01 | −0.3 |
| 5 | 0.5 | 0.9 | 4 | +0.02 | −0.2 |
| . | . | . | . | . | . |
| . | . | . | . | . | . |
| . | . | . | . | . | . |
| 359 | 0.5 | 1.1 | 358 | 0 | +0.5 |

The exposure map shown in Table 3 indicates that the processes from “Step 1” to “Step 359” are executed in order. As conditions for each step, four values are set: the exposure width (mm), the start angle (°), the wafer adjustment position (mm), and the mask height adjustment value (mm) (Step S14). The processing time indicates the execution time of the step, and the exposure width is the radial exposure range set based on the edge information. The start angle indicates the circumferential position Xθ (angle) at which the step is executed. For example, step 1 indicates that the process continues for 0.5 seconds with the exposure width adjusted to 1.1 mm when the circumferential position Xθ is in the range of 0° to 1°.

When these three setting values shown in Table 3 are used, the exposure controller 206 performs control so that the exposure width is 1.1 mm at the location where the circumferential position Xθ is 0°, for example. This is the same processing as the control in Table 2 shown above (Examples 1 to 6).

An exposure map in which the exposure position information, that is, the wafer adjustment position and the mask height adjustment value, is added to these three setting values will be described below. In Table 3, the wafer adjustment position is a setting value that moves the radial position of the wafer W (position in the Y-axis direction) by +0.01 mm from the reference position at a location where the circumferential position Xθ is 0°. The wafer adjustment position is a setting value that moves the radial position of the wafer W (position in the Y-axis direction) by +0.02 mm from the reference position at a location where the circumferential position Xθ is 1°.

In Table 3, the mask height adjustment value is a setting value that moves the mask height (position in the Z-axis direction) by +0.5 mm from the reference position at a location where the circumferential position Xθ is 1°. The mask height adjustment value is a setting value that moves the mask height by +0.4 mm from the reference position at a location where the circumferential position Xθ is 2°.

Next, the control device 100 executes Step S18. In Step S18, for example, the exposure controller 206 controls the periphery exposure apparatus U4 to expose the film F2 in the peripheral edge region of the front surface Wa in accordance with the exposure map including the exposure position information set in Step S17. Regarding this step, differences from Step S06 of FIG. 9 will be described. As shown in FIG. 19, the exposure controller 206 causes the exposure unit 120 (not shown) to irradiate the peripheral edge region of the front surface Wa with exposure light while rotating the wafer W held on the holding table 61. During this exposure irradiation, the exposure controller 206 drives the Y-axis direction adjuster 115 to adjust the Y-axis position and drives the Z-axis direction adjuster 116 to adjust the Z-axis position of the mask member 123 based on the exposure position information. The exposure controller 206 controls the positions of the holding table 61 and the drive mechanism 62 so that the adjustment values set in Table 3 are met. That is, the exposure controller 206 controls the exposure width, the adjustment position of the wafer W, and the mask height so that exposure is performed on the film F at the set exposure width for each angle for which the exposure width is set in the exposure map.

Although the Z-axis direction adjustment of the mask member 123 is shown to be performed by driving the Z-axis direction adjuster 116, the drive mechanism 124 connected to the mask member 123 may also change the position of the mask member 123 in the Z-axis direction.

Using the example shown in Table 3, the exposure controller 206 may control the exposure width to be 1.1 mm at a location where the circumferential position Xθ is 0°, for example, and at the same time, may move the radial position of the wafer W (position in the Y-axis direction) by +0.01 and the height of the mask by +0.5 mm. At this time, a correction value based on the height position of the mask and the radial position of the mask due to the movement of the radial position of the wafer W may be calculated, and the exposure width may be controlled to be 1.1 mm.

In this manner, the control device 100 detects the state of the wafer W held on the holding table 61 using the peripheral-end-portion measurement sensor 87 and the distance sensor 88 in the state detector 86 (Step S16). The control device 100 then additionally sets exposure position information in the exposure map based on the detected information, and controls the Y-axis position of the rotary holding unit 60 for each circumferential position Xθ and the Z-axis position of the mask member 123 using the set information. This makes it possible to perform exposure with an appropriate exposure width regardless of the state of the wafer W, such as warpage or the like. By detecting the state of the wafer W (Step S16) after the resist film formation and heat treatment (Step S15) and resetting the exposure map (Step S17), the exposure map may be set according to the state of the wafer W that has been deformed due to the resist film formation and heat treatment.

Next, the control device 100 executes Step S19, and then executes Step S20. Operations S19 and S20 are the same as Steps S07 and S08 in FIG. 9, respectively, and therefore will not be described further.

### Example 7

An example of calculating the wafer adjustment positions and the mask height adjustment values in Table 3 by measuring them using the state detector 86 will be described with reference to FIGS. 21A to 21C. The X-axis (Wafer Position) in FIG. 21A represents the position of the wafer W in the circumferential direction (θ-axis), and the Y-axis (Edge Position) represents the position from the center of the wafer W to the end of the wafer W. “E10” represents the edge position when the wafer W is not warped. The end position of the wafer W may be a value measured in advance using a reference wafer without warpage, or may be a theoretical value set in advance based on the radial size of the wafer. “E11” represents the wafer end position acquired by the warpage information acquisitor based on the measurement value obtained by the peripheral-end-portion measurement sensor 87 in the state detector 86. The end position of E11 is acquired for each position in the circumferential direction (θ-axis).

The wafer adjustment position in Table 3 may be calculated by finding the difference between the position of E10 and the position of E11 for each circumferential position, and calculating the amount of movement from the reference position based on the found circumferential position (θ axis). This calculation may be performed by the exposure map setter 203 of the control device 100.

Next, a description will be given using FIG. 21B. The X-axis (Wafer Position) in FIG. 21B represents the position of the wafer W in the circumferential direction (θ-axis), and the Y-axis (Wafer Height) represents the Z-axis position of the front surface Wa of the wafer W. “E12” represents the reference value when the wafer is not warped (0 mm). “E13” represents the position of the wafer W in the circumferential direction (θ-axis) when the distance sensor 88 in the state detector 86 measures the distance to the outer edge of the wafer W.

The mask height adjustment value in Table 3 may be calculated by finding the difference between the position of E12 and the position of E13 for each circumferential position, and calculating the amount of movement from the reference position based on the found circumferential position (θ axis). This calculation may be performed by the exposure map setter 203 of the control device 100.

Next, another example of a calculation method using Table 3 will be described. FIG. 21C is a correlation graph for calculating the wafer adjustment position of Table 3 from the Z-axis position of the outer edge obtained by measurement using the distance sensor 88. In FIG. 21C, the horizontal axis (Wafer Height) represents the difference in the Z-axis direction of the peripheral edge E13 from the reference position E12, and the vertical axis (Width Offset) represents the adjustment position of the wafer W in the radial direction (Y-axis direction) of wafer W.

The wafer adjustment position in Table 3 may be calculated by finding the difference between E13 and E12 (E13−E12) for each X axis (θ axis) in FIG. 21B and applying the found difference to the correlation graph in FIG. 21C. This calculation may be performed by the exposure map setter 203 of the control device 100. By performing the calculation using FIG. 21C, it is no longer necessary to calculate the wafer adjustment position using the peripheral-end-portion measurement sensor 87. In other words, the state of the wafer W may be determined using a smaller number of sensors.

### Example 8

Next, another control example using the periphery exposure apparatus U4 of FIG. 19 will be described. As shown in FIG. 19, the position of the holding table 61 in the Z axis direction may be set to a reference holding position A and a reference holding position B that is different from the reference holding position A. The reference holding position A and the reference holding position B may be changed by adjusting the Z-axis direction adjuster 116 under the control of the control device 100. While FIG. 19 shows an example in which the reference holding position A is higher in the Z axis direction than the reference holding position B, the present disclosure is not limited thereto. The reference holding position B may be set to a plurality of mounting positions, including an example in which the reference holding position B is higher than the reference holding position A.

When the wafer W held by the holding table 61 at the reference holding position A is warped upward, the peripheral edge of the wafer W may come into contact with the mask member 123. The exposure map setter 203 of the control device 100 may measure the position of the peripheral edge of the wafer W from the value of the distance sensor 88. When the measured position is equal to or greater than a predetermined threshold value, the exposure map setter 203 may determine that the wafer W will come into contact with the mask member 123. When it is determined that the wafer W will come into contact with the mask member 123, the control device 100 may control the Z-axis direction adjuster 116 during exposure to move the holding position of the holding table 61 from the mounting position A to the mounting position B. When the wafer W is moved to the mounting position B, the distance from the irradiator (the light source 121 and the optical system member 122) to the wafer W becomes longer. To compensate for this, the control device 100 may set the illuminance of the light source 121 to an increased value.

### Example 9

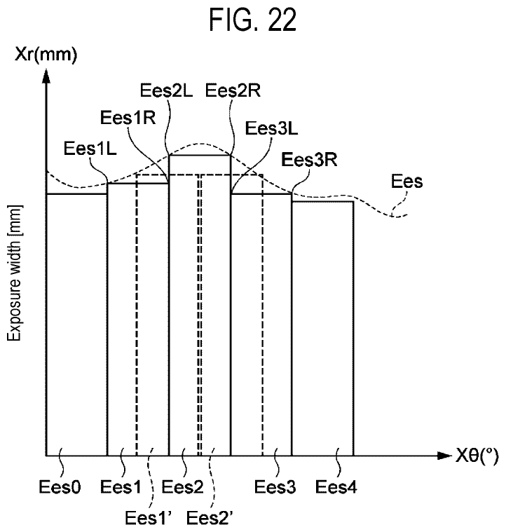

Another setting method for the exposure map setter 203 of the control device 100 will be described using FIG. 22. FIG. 22 is an enlarged view of the exposure map (exposure width Ees) shown in FIG. 13 in the Xθ-axis direction. Exposure widths Ees0 to Ees4 represent exposure widths set for each predetermined angle (for example, 1°) from the exposure width Ees. Reference positions Ees1L to Ees3L (left end) and reference positions Ees1R to Ees3R (right end) are reference positions when the exposure width is changed while continuously rotating the wafer W.

The difference in exposure width for each predetermined angle is confirmed from the exposure width Ees in the exposure map (exposure width Ees). For example, when the exposure width is wide, such as between Ees1 and Ees2, the reference position is set to a reference position Ees1L (left end), and the exposure width is set to match the exposure map (exposure width Ees). When the exposure width is narrow, such as between Ees2 and Ees3, the reference position is set to a reference position Ees2R, and the exposure width is set to match the exposure map (exposure width Ees). Although not shown, when there is no difference in exposure width, the reference position may be set to either the left end or the right end. By setting the reference position in this way after setting the exposure width, and then changing the reference position during exposure while rotating the wafer W, it is possible to set the exposure close to the exposure map (exposure width Ees).

Next, the exposure process will be described. Exposure is performed from the exposure width Ees1 through the exposure width Ees1′ to the exposure width Ees2 while changing the exposure width Ees1 based on the reference position Ees1L. Exposure is performed from the exposure width Ees2 through the exposure width Ees2′ to the exposure width Ees3 while changing the exposure widths Ees2 to Ees3 based on the reference position Ees2R.

In the above-described examples, the difference in exposure width is used for the description, but it may also be determined from the slope of the exposure map (exposure width Ees). The direction of the reference position may be changed as appropriate depending on the rotation direction of the wafer W, and the like.

### SUMMARY OF THE PRESENT DISCLOSURE

[1]

A substrate processing method includes: generating edge information indicating a relationship between a circumferential position around a center of a substrate and an outer edge position of a first film in a radial direction of the substrate based on an image obtained by capturing a peripheral edge region on a front surface of the substrate having the first film formed on the front surface; setting an exposure map indicating a relationship between the circumferential position and a set value of an exposure width in the radial direction based on the edge information; forming a second film on at least the peripheral edge region of the front surface after the image is obtained; obtaining warpage information of the substrate after the second film is formed; setting a relationship between the circumferential position and exposure position information of the substrate in the exposure map based on the warpage information; and performing an exposure on the second film in the peripheral edge region in accordance with the exposure map.

Using the example shown in FIG. 12B, a case where the negative resist material is used and the exposure width is set to a constant value is considered. For example, when the position of “Er1” shown in FIG. 12B is set to a position closest to the center of the exposure range, there may be a case where in a certain range in the circumferential direction, the outer edge of the film F1 is not covered by the film F2, and the film F0 below the film F1 is exposed. In this case, there is a possibility that a portion of the exposed film F0 affects the portion of the film F1 that is not covered by the film F2 and has a concave-convex pattern. Therefore, for example, the position of “Er2” shown in FIG. 12B is set to a position closest to the center of the exposure range when the exposure width is set to a constant value. For each individual wafer W, a constant exposure width is typically set without detecting the position of the outer edge of the film F1. In this case, assuming the worst case scenario, the exposure width is set further inward relative to the outer edge of the film F1. Thus, when the exposure width is set at the position of “Er2”, the region between the outer edge of the film F1 and the inner edge of the film F2 after exposure and development becomes larger. As a result, the annular film F2 formed in the peripheral edge region reduces the exposed region of the film F1 where the uneven pattern is formed. In the above-described substrate processing method, the exposure width may be set according to the shape of the outer edge of the film F1, so that the film F0 is not exposed and the reduction in the region of the film F1 capable of being formed with the uneven pattern due to the film F2 may be avoided. Similarly, even when the positive resist material is used, it is not necessary to remove more than necessary the peripheral edge of the resist film (film F2) formed using that resist material. Therefore, the reduction in the region of the film F2 capable of being formed with an uneven pattern due to the removal of the peripheral edge may be avoided.

Further, an example after the film F2 has been formed will be described using the example shown in FIG. 18. The state detector 86 includes the peripheral-end-portion measurement sensor 87 that measures the peripheral end portion of the wafer W held on the holding table 61 and the distance sensor 88 that measures the distance to the outer edge of the wafer W in the Z-axis direction (the direction perpendicular to the front surface Wa of the wafer W). The state detector 86 detects the state of warpage of the wafer W. By setting the state of warpage according to the warpage of the wafer W based on this state of warpage, it becomes possible to perform exposure without deviation of the exposure position due to the warpage of the wafer W.

[2]

The method of [1] above further includes: capturing the peripheral edge region of the front surface Wa of the wafer W to obtain the peripheral edge image.

In this case, it is possible to perform exposure that matches the state of the outer edge of an underlying film.

[3]

In the method of [1] or [2] above, the exposure width is set in the exposure map so that, for each predetermined angle, the position of one end of the exposed region closest to the center of the wafer W is shifted by a fixed value from the outer edge position (the outer edge position of the film F1) indicated by the edge information.

In this case, the exposure width may be set to a shape that more closely matches the shape of the outer edge of the film F1. Further, since it is only necessary to add or subtract a fixed value to or from the outer edge position of the film F1, the computational load when setting the exposure map may be reduced.

[4]

In the method of any one of [1] to [3] above, the exposure width is set in the exposure map for each predetermined angle, and the outer edge position is obtained in the edge information for each predetermined angle.

In this case, the outer edge position of the film F1 is calculated in the minimum angle unit required to set the exposure map. Therefore, the computational load when calculating the position of the outer edge of the film F1 from the peripheral edge image may be reduced.

[5]

The method of any one of [1] to [4] above further includes: after the exposure in accordance with the exposure map, performing a development so that the film F2 remains in the peripheral edge region; capturing the peripheral edge region of the front surface Wa of the wafer W after development of the film F2 to obtain a determination image; generating cut information indicating a relationship between the circumferential position Xθ and the inner edge position of the film F2 in the radial direction based on the determination image; and determining whether or not the exposure of the film F2 is normal based on a result of comparing the cut information with either the edge information or the exposure map.

In this case, the actual results after exposure are inspected. Therefore, it is possible to improve the reliability of the wafer W that has undergone periphery exposure.

[6]

The method of any one of [1] to [4] above further includes: performing a development so that a portion of the film F2 located in the peripheral edge region is removed after the exposure in accordance with the exposure map; capturing the peripheral edge region of the front surface Wa of the wafer W after the development of the film F2 to obtain a determination image; generating cut information indicating a relationship between the circumferential position Xθ and the outer edge position of the film F2 in the radial direction based on the determination image; and determining whether or not the exposure of the film F2 is normal based on a result of comparing the cut information with either the edge information or the exposure map.

In this case, the actual results after exposure are inspected. Therefore, it is possible to improve the reliability of the wafer W that has undergone periphery exposure.

[7]

In the method of any one of [1] to [6] above, the exposing the film F2 includes: irradiating the front surface Wa with exposure light via a mask member 123 having an opening 123a; and moving the mask member 123 in the radial direction to change the exposure width in accordance with the exposure map.

In this case, there is no need to drive or adjust the member and the optical system for irradiating the exposure light depending on the circumferential position during exposure. Therefore, it is easy to change the exposure width.

[8]

In the method of any one of [1] to [7] above, the exposing the film F2 includes: irradiating the front surface Wa with exposure light via a mask member 123 provided with an opening 123a and a shutter 125 capable of adjusting an opening degree of the opening 123a; and adjusting the opening degree with the shutter so as to change the exposure width in accordance with the exposure map.

In this case, there is no need to drive or adjust the member and the optical system for irradiating the exposure light depending on the circumferential position during exposure. Therefore, it is easy to change the exposure width.

[9]

In the method of any one of [1] to [7] above, the exposing the film F2 includes: irradiating the front surface Wa of the wafer W held on the holding table 111 with exposure light from an irradiator (the light source 121 and the optical system member 122) capable of irradiating the exposure light; and moving the holding table 111 to change the exposure width in accordance with the exposure map.

In this case, there is no need to drive or adjust the member and the optical system for irradiating the exposure light depending on the circumferential position during exposure. Therefore, it is easy to change the exposure width.

[10]

In the method of any one of [1] to [9] above, the exposure width and the rotation speed of the wafer W are set in the exposure map for each predetermined angle, the act of exposing the film F2 includes irradiating the front surface Wa with exposure light while changing the exposure width in a state in which the wafer W is continuously rotate in accordance with the exposure map, and the act of setting the exposure map includes repeatedly calculating a difference between an exposure width at a first angle and an exposure width at a second angle consecutive to the first angle while changing the second angle by the predetermined angle, and when a condition that the difference is smaller than a predetermined level is satisfied in a range including a predetermined number or more consecutive angles, setting the rotation speed within the range to a value greater than a speed reference value.

It is conceivable that periphery exposure is performed by changing the exposure width according to the circumferential position Xb (angle) while continuing to rotate the wafer W. In such periphery exposure, when the degree of change in exposure width is continuously small, it is easy to cause a device or a member for changing the exposure width to follow changes in the set value of the exposure width, even when the rotation speed of the wafer W increases. In the above method, when the condition that the difference between consecutive angles is smaller than a predetermined level is satisfied a predetermined number of times in succession, the rotation speed is set to a value greater than the reference value within the range. This shortens the processing time when performing periphery exposure while changing the exposure width. Accordingly, it is useful for both the exposure tailored to the condition of the outer edge of the underlying film and the maintenance of throughput.

[11]

In the method of [10] above, the illuminance of the exposure light is further set in the exposure map for each predetermined angle, the act of exposing the film F2 includes irradiating the front surface Wa with the exposure light while adjusting the illuminance in accordance with the exposure map, and the act of setting the exposure map further includes setting the illuminance of the exposure light to a value greater than an illuminance reference value in a range where the rotation speed is set to a value greater than the speed reference value.

In this case, it is possible to reduce the difference in the exposure amount (for example, dose) of the exposure light between a range where the rotation speed is faster than in other range and the other range. Accordingly, even when the rotation speed is increased to shorten the processing time, the exposure state may be made uniform across the front surface Wa of one wafer W.

[12]

In the method of any one of [1] to [11] above, the exposure width and the rotation speed of the wafer W are set in the exposure map for each predetermined angle, the act of exposing the film F2 includes irradiating the front surface Wa with exposure light while changing the exposure width in a state in which the wafer W is continuously rotate in accordance with the exposure map, and the act of setting the exposure map includes repeatedly calculating a difference between an exposure width at a first angle and an exposure width at a second angle consecutive to the first angle while changing the second angle by the predetermined angle and setting the rotation speed at an angle at which the condition that the difference is greater than a predetermined level to a value greater than a speed reference value.

It is conceivable that periphery exposure is performed by changing the exposure width according to the circumferential position Xb (angle) while continuing to rotate the wafer W. In such periphery exposure, when the exposure width is changed significantly, it is difficult to cause a device or a member for changing the exposure width to follow changes in the set value of the exposure width. In the above method, the rotation speed is set to a value smaller than the speed reference value at angles at which the exposure width is changed significantly. Even when there are portions where the exposure width is changed significantly, it is easy to cause a device or a member for changing the exposure width to follow the change in the exposure width, and therefore, it is possible to simplify the device or the member.

[13]

In the method of [12] above, the illuminance of the exposure light is further set in the exposure map for each predetermined angle, the act of exposing the film F2 includes irradiating the front surface Wa with the exposure light while adjusting the illuminance in accordance with the exposure map, and the act of setting the exposure map includes setting the illuminance of the exposure light at angles at which the rotation speed is set to a value smaller than the speed reference value to a value smaller than an illuminance reference value.

In this case, the difference in the exposure amount (for example, dose) of the exposure light between the angle (range) where the rotation speed is slower than in other range and the other range may be reduced. Accordingly, the exposure state within the front surface Wa of one wafer W may be made uniform.

[14]

In the method of any one of [1] to [14] above, the exposing the film F2 includes: irradiating the front surface Wa with exposure light via a mask member 123 having an opening, the exposure width and the position of the mask member 123 in a direction in which the exposure light is emitted are set in the exposure map for each predetermined angle, the act of exposing the film F2 further includes adjusting the position of the mask member 123 in the direction in which the exposure light is emitted in accordance with the exposure map, and the act of setting the exposure map includes setting the position of the mask member 123 in the direction in which the exposure light is emitted for each predetermined angle based on warpage information indicating a state of warpage in the peripheral edge region of the front surface Wa.

When there is a warped portion in the peripheral edge region of the wafer W, the region actually irradiated with the exposure light may differ even when the set value of the exposure width remains the same. In the above method, the position of the mask member 123 is also changed based on the warpage information. Therefore, it is possible to suppress occurrence of differences in the region actually irradiated with the exposure light due to warpage, even when the peripheral edge region of the wafer W includes a warped portion. Accordingly, exposure may be performed precisely in accordance with the state of the outer edge of the underlying film.

[15]

A substrate processing apparatus (wafer processing system 1) includes: a film former (film processing apparatus U1 and heat treatment apparatus U2) configured to form a film on a front surface Wa of a wafer W; a periphery exposure apparatus U4 configured to expose a peripheral edge region of the front surface Wa; an image information acquisitor 201 configured to acquire a peripheral edge image by capturing the peripheral edge region of the front surface Wa of the wafer W having a film F1 formed on the front surface Wa; an edge information generator 202 configured to generate edge information indicating a relationship between a circumferential position Xθ around the center of the wafer W and an outer edge position of the film F1 in a radial direction of the wafer W based on the peripheral edge image; an exposure map setter 203 configured to set an exposure map indicating a relationship between the circumferential position Xθ and a set value of an exposure width in the radial direction based on the edge information; a film formation controller 205 configured to control the film former to form a film F2 on at least the peripheral edge region of the front surface Wa after the peripheral edge image is obtained; and an exposure controller 206 configured to control the periphery exposure apparatus U4 to expose the film F2 in the peripheral edge region in accordance with the exposure map.

In this substrate processing apparatus, similarly to the substrate processing method described in [1] above, it is possible to perform exposure in accordance with the state of the outer edge of an underlying film.

### SUPPLEMENTARY NOTES

### [Supplementary Note 1]

A substrate processing method includes:
generating edge information indicating a relationship between a circumferential position around a center of a substrate and an outer edge position of a first film in a radial direction of the substrate based on an image obtained by capturing a peripheral edge region on a front surface of the substrate having the first film formed on the front surface;
setting an exposure map indicating a relationship between the circumferential position and a set value of an exposure width in the radial direction based on the edge information;
forming a second film on at least the peripheral edge region of the front surface after the image is obtained;
obtaining warpage information of the substrate after the second film is formed;
setting a relationship between the circumferential position and exposure position information of the substrate in the exposure map based on the warpage information; and
performing an exposure on the second film in the peripheral edge region in accordance with the exposure map.

### [Supplementary Note 2]

In the method of Supplementary Note 1 above, in the exposure map, the exposure width is set so that the position of one end of an exposure range close to the center of the substrate W is shifted by a certain value from the outer edge position indicated by the edge information.

### [Supplementary Note 3]

In the method of Supplementary Note 1 or 2 above, in the exposure map, the exposure width is set for each predetermined angle, and in the edge information, the outer edge position is obtained for each predetermined angle.

### [Supplementary Note 4]

The method of Supplementary Note 1 or 2 above further includes:
after the exposure in accordance with the exposure map is performed, performing a development so that the second film F2 remains in the peripheral edge region;
capturing the peripheral edge region of the front surface Wa of the substrate W after the development of the second film F2 to obtain a second image;
generating cut information indicating a relationship between the circumferential position Xθ and an inner edge position of the second film F2 in the radial direction based on the second image; and
determining whether or not the exposure of the second film F2 is normal based on a result of comparing the cut information with either the edge information or the exposure map.

### [Supplementary Note 5]

The method of Supplementary Note 1 or 2 above further includes:
after the exposure in accordance with the exposure map is performed, performing a development so that a portion of the second film F2 located in the peripheral edge region is removed;
capturing the peripheral edge region of the front surface Wa of the substrate W after the development of the second film F2 to obtain a second image;
generating cut information indicating a relationship between the circumferential position Xθ and an outer edge position of the second film F2 in the radial direction based on the second image; and
determining whether or not the exposure of the second film F2 is normal based on a result of comparing the cut information with either the edge information or the exposure map.

### [Supplementary Note 6]

In the method of Supplementary Note 1 or 2 above, the performing the exposure on the second film F2 includes irradiating the front surface Wa with exposure light via a mask member 123 having an opening, and moving the mask member 123 in the radial direction to change the exposure width in accordance with the exposure map.

### [Supplementary Note 7]

In the method of Supplementary Note 1 or 2, the performing the exposure on the second film F2 includes irradiating the front surface Wa with exposure light via a mask member 123 having an opening and a shutter capable of adjusting an opening degree of the opening, and adjusting the opening degree with the shutter 125 so as to change the exposure width in accordance with the exposure map.

### [Supplementary Note 8]

In the method of Supplementary Note 1 or 2 above, the performing the exposure on the second film F2 includes irradiating the front surface Wa of the substrate W held by a holder with exposure light from an irradiator capable of irradiating the exposure light, and moving the holder to change the exposure width in accordance with the exposure map.

### [Supplementary Note 9]

In the method of Supplementary Note 1 or 2 above, the obtaining the warpage information includes obtaining a position of a peripheral end portion of the substrate W, obtaining a distance from the front surface Wa of the substrate W to the outer edge portion of the substrate W in the vertical direction, and obtaining the position of the peripheral end portion and the distance in the vertical direction by measurement from a back surface side of the substrate W.

### [Supplementary Note 10]

The method of Supplementary Note 9 above further includes:
calculating a substrate adjustment position from a difference between the position of the peripheral end portion and a preset reference position to set the substrate adjustment position in the exposure map as exposure position information; and
adjusting the position of a holder configured to hold the substrate W based on the substrate adjustment position.

### [Supplementary Note 11]

In the method of Supplementary Note 9 above, the performing the exposure on the second film F2 includes irradiating the front surface Wa with exposure light via a mask member having an opening, setting a mask height adjustment value as the exposure position information in the exposure map, the mask height adjustment value being calculated from a difference between a distance from the front surface Wa of the substrate W to the outer edge portion of the substrate in the vertical direction and a preset reference position, and adjusting the position of the mask member 123 based on the mask height adjustment value.

### [Supplementary Note 12]

The method of Supplementary Note 11 above further includes:
setting a substrate adjustment position as the exposure position information in the exposure map, the substrate adjustment position being calculated from a correlation formula between a difference between a distance from the front surface Wa of the substrate W to the outer edge portion of the substrate in the vertical direction and a preset reference position, and a position adjustment value for adjusting the position of the substrate W in the radial direction; and
adjusting the position of a holder configured to hold the substrate W based on the substrate adjustment position.

### [Supplementary Note 13]

In the method of Supplementary Note 9 above, the performing the exposure on the second film F2 includes irradiating the front surface Wa with exposure light via a mask member having an opening, determining whether or not the substrate comes into contact with the mask member 123 based on information acquired by a distance sensor, and, when the substrate is determined to come into contact with the mask member, changing the position of a holder configured to hold the substrate W to a second position lower than a first position.

### [Supplementary Note 14]

In the method of Supplementary Note 2 above, the exposure width is set in the exposure map for each predetermined angle, and
the method further includes:
setting a reference position for setting the exposure width based on a difference in exposure width for each predetermined angle; and
setting the exposure width in conformity with the reference position.

### [Supplementary Note 15]

A substrate processing apparatus 1 includes:
a film former configured to form a film on a front surface Wa of a substrate W;
a holder configured to hold the substrate W;
a periphery exposer U4 configured to expose a peripheral edge region of the front surface Wa of the substrate W held by the holder;
an image information acquisitor 201 configured to acquire an image obtained by capturing the peripheral edge region of the front surface Wa of the substrate W having a first film F1 formed on the front surface Wa;
an edge information generator 202 configured to generate edge information indicating a relationship between a circumferential position around a center of the substrate W and an outer edge position of the first film F1 in a radial direction of the substrate W based on the image;
a film formation controller 205 configured to control the film former to form a second film F2 on at least the peripheral edge region of the front surface Wa after the image is obtained;
a state detector 86 configured to acquire warpage information of the substrate W after controlling a film formation;
an exposure map setter 203 configured to set an exposure map indicating a relationship between the circumferential position Xθ, a set value of the exposure width in the radial direction, and exposure position information of the substrate W based on the edge information and the warpage information; and
an exposure controller 206 configured to control the periphery exposer U4 and the holder to expose the second film F2 in the peripheral edge region in accordance with the exposure map.

### [Supplementary Note 16]

The apparatus of Supplementary Note 15, wherein the state detector 86 includes at least one of a peripheral-end-portion measurement sensor 87 configured to measure a position of a peripheral end portion of the front substrate W or a distance sensor 88 configured to measure a distance from the front surface Wa of the substrate W to the outer edge portion of the substrate W in the vertical direction, and
the peripheral-end-portion measurement sensor 87 and the distance sensor 88 are provided at positions facing a back surface of the substrate W.

### [Supplementary Note 17]

In the apparatus of Supplementary Note 16 above, the holder includes a radial direction adjuster 115 configured to adjust a radial position of the substrate W,
the exposure map setter 203 sets a substrate adjustment position as the exposure position information based on a difference between a preset reference position and a measurement value obtained by the peripheral-end-portion measurement sensor 87 for each predetermined angle, and
the exposure controller 206 adjusts the radial direction adjuster 115 for each predetermined angle to match the substrate adjustment position.

### [Supplementary Note 18]

In the apparatus of Supplementary Note 16 above, the periphery exposer U4 includes a mask member 123 configured to adjust a range of light for exposing the front surface Wa of the substrate W, and a drive configured to adjust a position of the mask member 123 in the vertical direction from the front surface Wa of the substrate W,
the exposure map sets a mask height adjustment value as the exposure position information based on a difference between a preset reference position and a measurement value obtained by the distance sensor 88 for each predetermined angle, and
the exposure controller 206 operates the drive for each predetermined angle of the substrate W based on the mask height adjustment value.

### [Supplementary Note 19]

In the apparatus of Supplementary Note 16 above, the holder includes a vertical direction adjuster 116 configured to adjust the vertical position of the front surface Wa of the substrate W,
the periphery exposer U4 includes a mask member 123 configured to adjust a range of light for exposing the front surface Wa of the substrate W, and
the exposure controller 206 determines whether or not the substrate comes into contact with the mask member 123 based on information acquired by the distance sensor 88 and, when the substrate is determined to come into contact with the mask member, adjusts the vertical direction adjuster 116 to adjust the position of the holder to a second position lower than a first position.

### [Supplementary Note 20]

In the apparatus of Supplementary Note 16 above, the holder includes a radial direction adjuster 115 configured to adjust the radial position of the substrate W, and
the exposure map setter 203 sets a substrate adjustment position as the exposure position information for each predetermined angle based on a correlation formula between a difference between a distance from the front surface Wa of the substrate W to the outer edge in the vertical direction measured by the distance sensor 88 and a preset reference position, and a position adjustment value for adjusting the radial position of the substrate W, and adjusts the position of the radial direction adjuster for each predetermined angle based on the substrate adjustment position.

According to the present disclosure in some embodiments, it is possible to provide a substrate processing method and a substrate processing apparatus capable of performing periphery exposure in conformity with the position of a substrate during exposure according to the state of warpage and the state of the outer edge of an underlying film.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
generating edge information indicating a relationship between a circumferential position around a center of a substrate and an outer edge position of a first film in a radial direction of the substrate based on an image obtained by capturing a peripheral edge region on a front surface of the substrate having the first film formed on the front surface;
setting an exposure map indicating a relationship between the circumferential position and a set value of an exposure width in the radial direction based on the edge information;
forming a second film on at least the peripheral edge region of the front surface after the image is obtained;
obtaining warpage information of the substrate after the second film is formed;
setting a relationship between the circumferential position and exposure position information of the substrate in the exposure map based on the warpage information; and
performing an exposure on the second film in the peripheral edge region in accordance with the exposure map.

2. The method of claim 1, wherein in the exposure map, the exposure width is set so that a position of one end of an exposure range close to the center of the substrate is shifted by a certain value from the outer edge position indicated by the edge information.

3. The method of claim 1, wherein in the exposure map, the exposure width is set for each predetermined angle, and in the edge information, the outer edge position is obtained for each predetermined angle.

4. The method of claim 1, further comprising:
after the exposure in accordance with the exposure map is performed, performing a development so that the second film remains in the peripheral edge region;
capturing the peripheral edge region of the front surface of the substrate after the development of the second film to obtain a second image;
generating cut information indicating a relationship between the circumferential position and an inner edge position of the second film in the radial direction based on the second image; and
determining whether or not the exposure of the second film is normal based on a result of comparing the cut information with either the edge information or the exposure map.

5. The method of claim 1, further comprising:
after the exposure in accordance with the exposure map is performed, performing a development so that a portion of the second film located in the peripheral edge region is removed;
capturing the peripheral edge region of the front surface of the substrate after the development of the second film to obtain a second image;
generating cut information indicating a relationship between the circumferential position and an outer edge position of the second film in the radial direction based on the second image; and
determining whether or not the exposure of the second film is normal based on a result of comparing the cut information with either the edge information or the exposure map.

6. The method of claim 1, wherein the performing the exposure on the second film includes:
irradiating the front surface with exposure light via a mask member having an opening; and
moving the mask member in the radial direction to change the exposure width in accordance with the exposure map.

7. The method of claim 1, wherein the performing the exposure on the second film includes:
irradiating the front surface with exposure light via a mask member in which an opening and a shutter capable of adjusting an opening degree of the opening are provided; and
adjusting the opening degree with the shutter so as to change the exposure width in accordance with the exposure map.

8. The method of claim 1, wherein the performing the exposure on the second film includes:
irradiating the front surface of the substrate held by a holder with exposure light from an irradiator capable of irradiating the exposure light; and
moving the holder to change the exposure width in accordance with the exposure map.

9. The method of claim 1, wherein the obtaining the warpage information includes:
obtaining a position of a peripheral end portion of the substrate;
obtaining a distance from the front surface of the substrate to an outer edge portion of the substrate in the vertical direction; and
obtaining the position of the peripheral end portion and the distance in the vertical direction by measurement from a back surface side of the substrate.

10. The method of claim 9, further comprising:
calculating a substrate adjustment position from a difference between the position of the peripheral end portion and a preset reference position to set the substrate adjustment position in the exposure map as the exposure position information; and
adjusting a position of a holder configured to hold the substrate based on the substrate adjustment position.

11. The method of claim 9, wherein the performing the exposure on the second film includes:
irradiating the front surface with exposure light via a mask member having an opening;
setting a mask height adjustment value as the exposure position information in the exposure map, the mask height adjustment value being calculated from a difference between a distance from the front surface of the substrate to the outer edge portion of the substrate in the vertical direction and a preset reference position; and
adjusting a position of the mask member based on the mask height adjustment value.

12. The method of claim 11, further comprising:
setting a substrate adjustment position as the exposure position information in the exposure map, the substrate adjustment position being calculated from a correlation formula between a difference between a distance from the front surface of the substrate to the outer edge portion of the substrate in the vertical direction and a preset reference position, and a position adjustment value for adjusting the position of the substrate in the radial direction; and
adjusting a position of a holder configured to hold the substrate based on the substrate adjustment position.

13. The method of claim 9, wherein the performing the exposure on the second film includes:
irradiating the front surface with exposure light via a mask member having an opening;
determining whether or not the substrate comes into contact with the mask member based on information acquired by a distance sensor; and
when the substrate is determined to come into contact with the mask member, changing a position of a holder configured to hold the substrate to a second position lower than a first position.

14. The method of claim 2, wherein the exposure width is set in the exposure map for each predetermined angle, and
wherein the method further comprises:
setting a reference position for setting the exposure width based on a difference in exposure width for each predetermined angle; and
setting the exposure width in conformity with the reference position.

15. A substrate processing apparatus, comprising:
a film former configured to form a film on a front surface of a substrate;
a holder configured to hold the substrate;
a periphery exposer configured to expose a peripheral edge region of the front surface of the substrate held by the holder;
an image information acquisitor configured to acquire an image obtained by capturing the peripheral edge region of the front surface of the substrate having a first film formed on the front surface;
an edge information generator configured to generate edge information indicating a relationship between a circumferential position around a center of the substrate and an outer edge position of the first film in a radial direction of the substrate based on the image;
a film formation controller configured to control the film former to form a second film on at least the peripheral edge region of the front surface after the image is obtained;
a state detector configured to acquire warpage information of the substrate after controlling a film formation;
an exposure map setter configured to set an exposure map indicating a relationship between the circumferential position, a set value of an exposure width in the radial direction, and exposure position information of the substrate based on the edge information and the warpage information; and
an exposure controller configured to control the periphery exposer and the holder to expose the second film in the peripheral edge region in accordance with the exposure map.

16. The substrate processing apparatus of claim 15, wherein the state detector includes:
at least one of a peripheral-end-portion measurement sensor configured to measure a position of a peripheral end portion of the front substrate or a distance sensor configured to measure a distance from the front surface of the substrate to an outer edge portion of the substrate in the vertical direction, and
wherein the peripheral-end-portion measurement sensor and the distance sensor are provided at positions facing a back surface of the substrate.

17. The substrate processing apparatus of claim 16, wherein the holder includes a radial direction adjuster configured to adjust a radial position of the substrate,
wherein the exposure map setter sets a substrate adjustment position as the exposure position information based on a difference between a preset reference position and a measurement value obtained by the peripheral-end-portion measurement sensor for each predetermined angle, and
wherein the exposure controller adjusts the radial direction adjuster for each predetermined angle to match the substrate adjustment position.

18. The substrate processing apparatus of claim 16, wherein the periphery exposer includes:
a mask member configured to adjust a range of light for exposing the front surface of the substrate; and
a drive configured to adjust a position of the mask member in the vertical direction from the front surface of the substrate, and
wherein the exposure map sets a mask height adjustment value as the exposure position information based on a difference between a preset reference position and a measurement value obtained by the distance sensor for each predetermined angle, and
wherein the exposure controller operates the drive for each predetermined angle of the substrate based on the mask height adjustment value.

19. The substrate processing apparatus of claim 16, wherein the holder includes a vertical direction adjuster configured to adjust a vertical position of the front surface of the substrate,
wherein the periphery exposer includes a mask member configured to adjust a range of light for exposing the front surface of the substrate, and
wherein the exposure controller determines whether or not the substrate comes into contact with the mask member based on information acquired by the distance sensor and, when the substrate is determined to come into contact with the mask member, adjusts the vertical direction adjuster to adjust a position of the holder to a second position lower than a first position.

20. The substrate processing apparatus of claim 16, wherein the holder includes a radial direction adjuster configured to adjust a radial position of the substrate, and
wherein the exposure map setter sets a substrate adjustment position as the exposure position information for each predetermined angle based on a correlation formula between a difference between the distance from the front surface of the substrate to the outer edge portion in the vertical direction, which is measured by the distance sensor, and a preset reference position, and a position adjustment value for adjusting the radial position of the substrate, and adjusts a position of the radial direction adjuster for each predetermined angle based on the substrate adjustment position.
